(19) United States
(12) Patent Application Publication
(10) Pub. No.: US 2026/0113966 A1
(43) Pub. Date: Apr. 23, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Pin-Wen CHEN, Keelung City (TW); Chih-Chieh LEE, Taipei City (TW); Hung-Chang HSU, Kaohsiung (TW); Wei-Jung LIN, Hsinchu City (TW); Pei-Wen WU, Xinfeng Township (TW); Pei Shan CHANG, Taipei (TW); Li-Wei CHU, New Taipei City (TW); Pei-Hsuan LEE, Taipei City (TW); Chih-Chien CHI, Hsinchu City (TW); Wei-Yip LOH, Hsinchu City (TW); Chun-Hsien HUANG, Hsinchu (TW); Chih-Wei CHANG, Hsin-Chu (TW); Ming-Hsing TSAI, Chu-Pei City (TW)

(21) Appl. No.: 19/027,891

(22) Filed: Jan. 17, 2025

Related U.S. Application Data
(60) Provisional application No. 63/698,632, filed on Sep. 25, 2024.

(51) Int. Cl. H10D 30/01; H10D 30/00; H10D 62/13; H10D 64/23

(52) U.S. Cl. CPC H10D 30/0198; H10D 30/501; H10D 62/151; H10D 64/251

(57) ABSTRACT

A source/drain region is formed for a nanostructure transistor of a semiconductor device such that a hollow cavity extends into the source/drain region from a top of the source/drain region into the source/drain region. In some implementations, the cavity extends fully through the depth of the source/drain region. The cavity results from partial epitaxial growth of one or more epitaxial layers of the source/drain region. A metal core of the source/drain region is formed in the cavity and electrically coupled to a source/drain contact of a nanostructure transistor such that electrically conductive material is recessed within the source/drain region. This provides a greater amount of surface area for the source/drain contact to contact the source/drain region than if the source/drain region were fully filled in with epitaxially-grown semiconductor material.

### CROSS-REFERENCE TO RELATED APPLICATION

This Patent Application claims priority to U.S. Provisional Patent Application No. 63/698,632, filed on Sep. 25, 2024, and entitled “SEMICONDUCTOR DEVICE AND METHODS OF FORMATION.” The disclosure of the prior Application is considered part of and is incorporated by reference into this Patent Application.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A and 4B are diagrams of an example implementation of an inner spacer formation process described herein.

FIGS. 5A-5C are diagrams of an example implementation of a source/drain region formation process described herein.

FIG. 6 is a diagram of an example implementation of an interlayer dielectric formation process described herein.

FIGS. 7A and 7B are diagrams of an example implementation of a replacement gate process described herein.

FIGS. 8A-8F are diagrams of an example implementation of a source/drain contact formation process described herein.

FIGS. 9A-9D are diagrams of an example implementation of a source/drain contact formation process described herein.

FIGS. 10A-10F are diagrams of an example implementation of a source/drain contact formation process described herein.

FIGS. 11A-11D are diagrams of an example implementation of a source/drain contact formation process described herein.

FIGS. 12A-12E are diagrams of an example implementation of a source/drain contact formation process described herein.

FIG. 13 is a diagram of an example implementation of a semiconductor device described herein.

FIGS. 14A-14E are diagrams of an example implementation of a source/drain contact formation process described herein.

FIG. 15 is a flowchart of an example process associated with forming a semiconductor device described herein.

FIG. 16 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Nanostructure transistors (e.g., nanowire transistors, nanosheet transistors, GAA transistors, multi-bridge channel transistors, nanoribbon transistors, and/or other types of nanostructure transistors) may overcome one or more of the above-described drawbacks of some types of transistors. However, nanostructure transistors face fabrication challenges that can cause performance issues, manufacturing yield issues, and/or device failures.

For example, various parts of a nanostructure transistor may be susceptible to increased resistance as feature sizes are reduced. One such part of a nanostructure transistor that is susceptible to increased resistance is the connection between a source/drain region of the nanostructure transistor and a source/drain contact formed on the source/drain region. As the sizes (e.g., the lateral widths) of the source/drain region and the source/drain contact are reduced, the contact surface area between the source/drain region and the source/drain contact is reduced. The reduced contact surface area between the source/drain region and the source/drain contact restricts the flow of electrons between the source/drain region and the source/drain contact, which increases current crowding around the source/drain region and the source/drain contact. The increased current crowding results in increased contact resistance between the source/drain region and the source/drain contact. This can lead to reduced power efficiency for the nanostructure transistor and/or reduced switching speeds for the nanostructure transistor, among other examples.

In some implementations described herein, a source/drain region is formed for a nanostructure transistor of a semiconductor device such that a hollow cavity extends into the source/drain region from a top of the source/drain region into the source/drain region. In some implementations, the cavity extends fully through the depth of the source/drain region. The cavity results from partial epitaxial growth of one or more epitaxial layers of the source/drain region. A metal core of the source/drain region is formed in the cavity and electrically coupled to a source/drain contact of a nanostructure transistor such that electrically conductive material is recessed within the source/drain region. This provides a greater amount of surface area for the source/drain contact to contact the source/drain region than if the source/drain region were fully filled in with epitaxially-grown semiconductor material. The increased contact surface area provides for reduced contact resistance between the source/drain region and the source/drain contact, because of the less-restricted current flow path between the source/drain region and the source/drain contact. In this way, the reduced contact resistance between the source/drain region and the source/drain contact enables a greater power efficiency to be achieved for the nanostructure transistor and/or enables increased switching speeds to be achieved for the nanostructure transistor, among other examples.

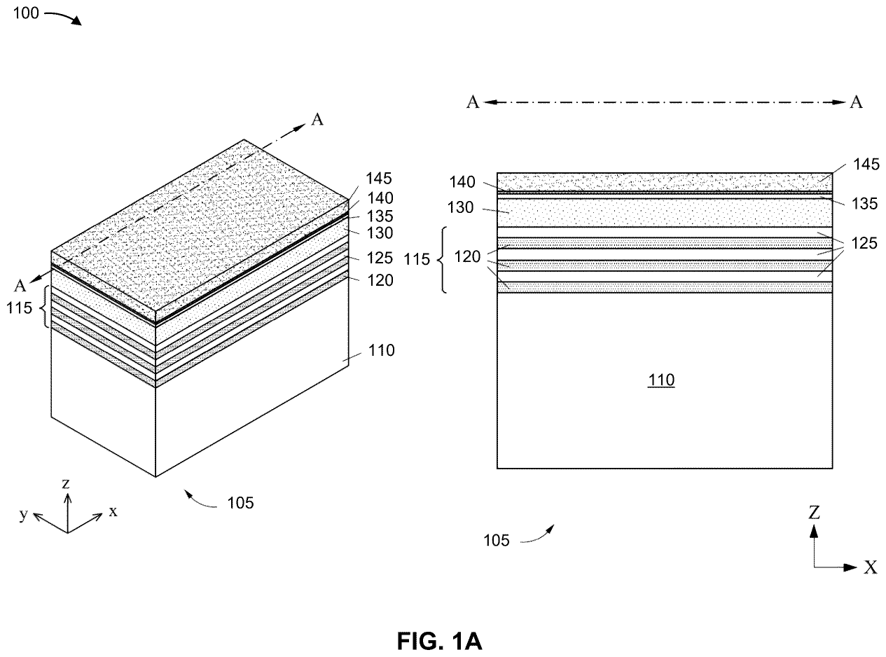

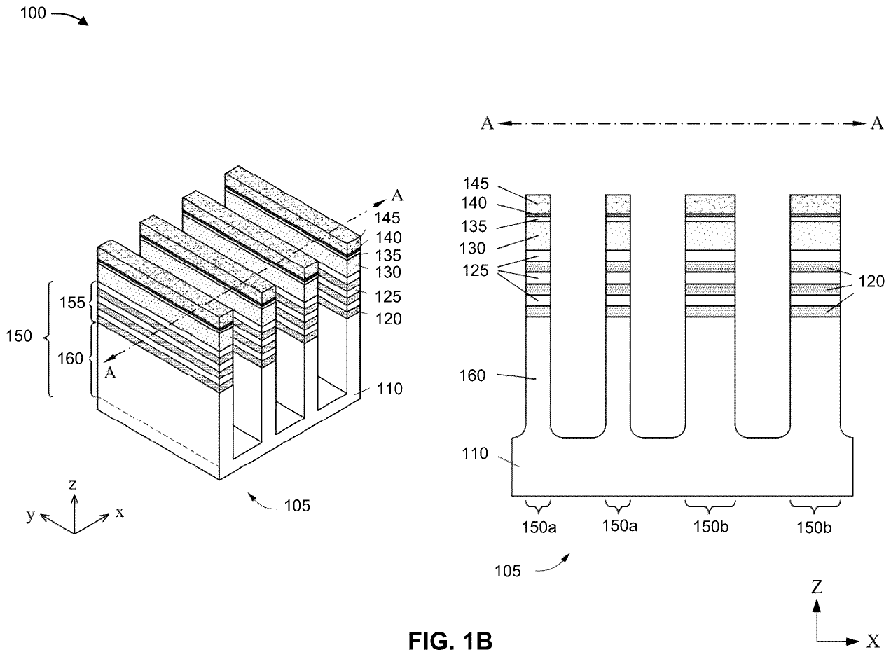

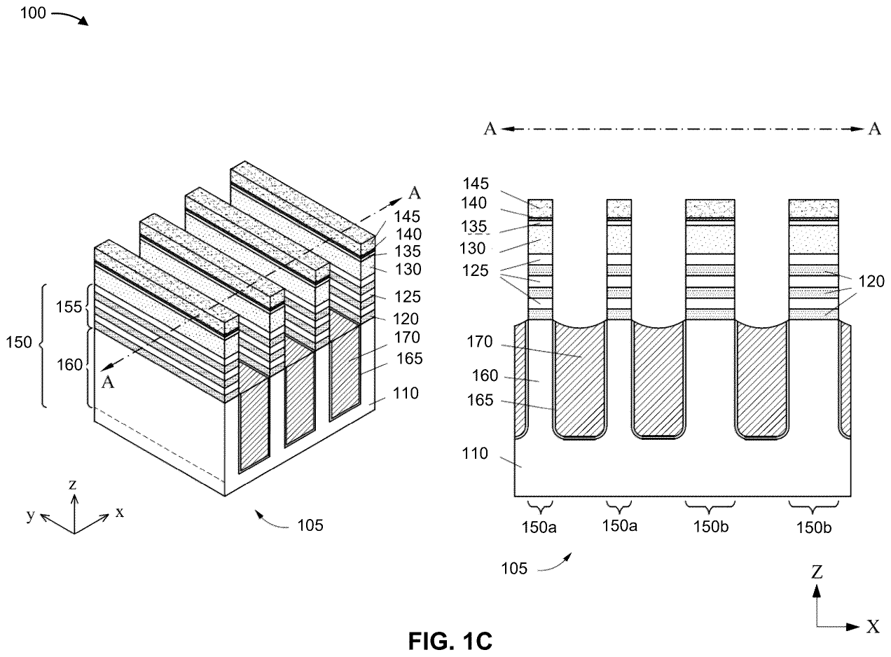

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIG. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

One or more masking layers may be form (e.g., using one or more deposition tools) on the layer stack 115. The masking layer(s) may include a hard mask (HM) layer 130, a capping layer 135, an oxide layer 140, and/or a nitride layer 145. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 150 that extend above the semiconductor substrate 110. The fin structures 150 may extend in a y-direction in the semiconductor device 105 and may be arranged in an x-direction in the semiconductor device 105. A fin structure 150 includes a portion 155 of the layer stack 115 over and/or on a fin portion 160 above the semiconductor substrate 110. The fin structures 150 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 150 may be formed to have different widths for different types of nanostructure transistors. As an example, a first subset of fin structures 150a may be formed for p-type nanostructure transistors (e.g., p-type metal oxide semiconductor (PMOS) nanostructure transistors), and a second subset of fin structures 150b may be formed for n-type nanostructure transistors (e.g., n-type metal oxide semiconductor (NMOS) nanostructure transistors). As another example, a first subset of fin structures 150a may be formed for nanostructure transistors that are configured to operate at lower voltages, and a second subset of fin structures 150b may be formed for nanostructure transistors that are configured to operate at higher voltages.

As shown in FIG. 1C, a liner 165 and STI regions 170 are formed between adjacent fin portions 160 of the fin structures 150. The liner 165 and the STI regions 170 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner (e.g., using ALD or another conformal deposition technique), and may deposit a dielectric layer (e.g., using CVD, PVD, a ALD, and/or another suitable deposition technique) on the liner 165 such that the dielectric layer fully fills in the spaces between the fin structures 150 and extends above the tops of the fin structures 150. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 145. The nitride layer 145 functions as a CMP stop layer in the planarization operation. An etch tool may be used to then etch the dielectric layer to form the STI regions 170 such that the top surfaces of the STI region 170 are approximately co-planar with or below the bottom-most sacrificial nanostructure layer 120.

As indicated above, FIGS. 1A-1C are provided as an example. Other examples may differ from what is described with regard to FIGS. 1A-1C.

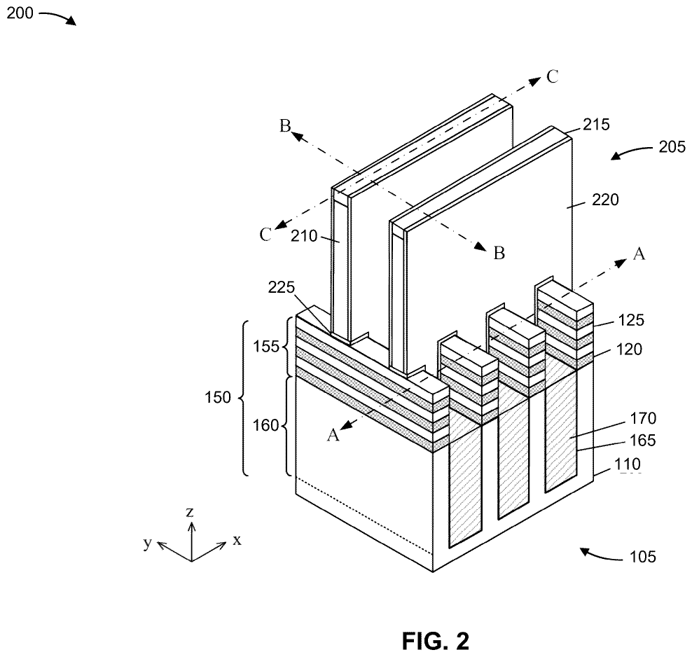

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 700 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 150 and portions of the STI regions 170. The dummy gate structures 205 extend in the x-direction and are arranged in the y-direction such that the dummy gate structures 205 are approximately perpendicular to the fin structures 150. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 150.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 150 in the source/drain areas of the semiconductor device 105. Cross-section B-B is in a y-z plane (referred to as an x-cut) perpendicular to the cross-section A-A, and is across the dummy gate structures 205 and along an underlying fin structure 150. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

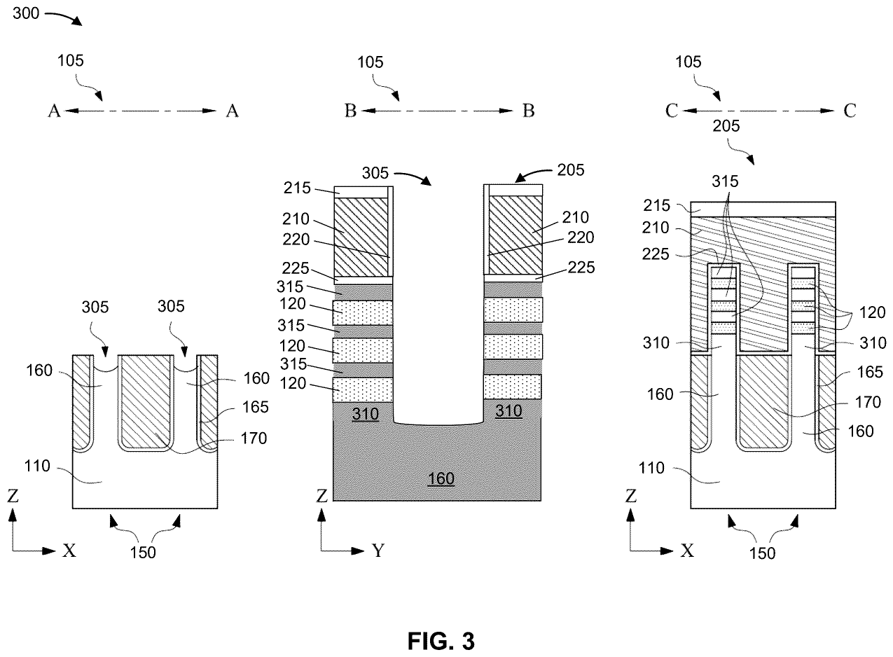

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 155 of a fin structure 150 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 160 of the fin structure 150. This results in formation of mesa regions 310 in the fin structure 150. The sidewalls of the portions of each source/drain recess 305 below the layer stack 115 correspond to sidewalls of mesa regions 310. A mesa region 310 (also referred to as pedestals) refers to a region of the fin portion 160 of the fin structure 150 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

In some implementations, the sidewalls of a source/drain recess 305 may be substantially vertical and may extend primarily in the z-direction. In some implementations, the sidewalls of a source/drain recess 305 may be tapered and may extend at opposing angles relative to the bottom surface of the source/drain recess 305. In these implementations, the y-direction width at the top of the source/drain recess 305 may be greater than the y-direction width at the bottom of the source/drain recess 305.

As indicated above, FIG. 3 is provided as an example. Other examples may differ from what is described with regard to FIG. 3.

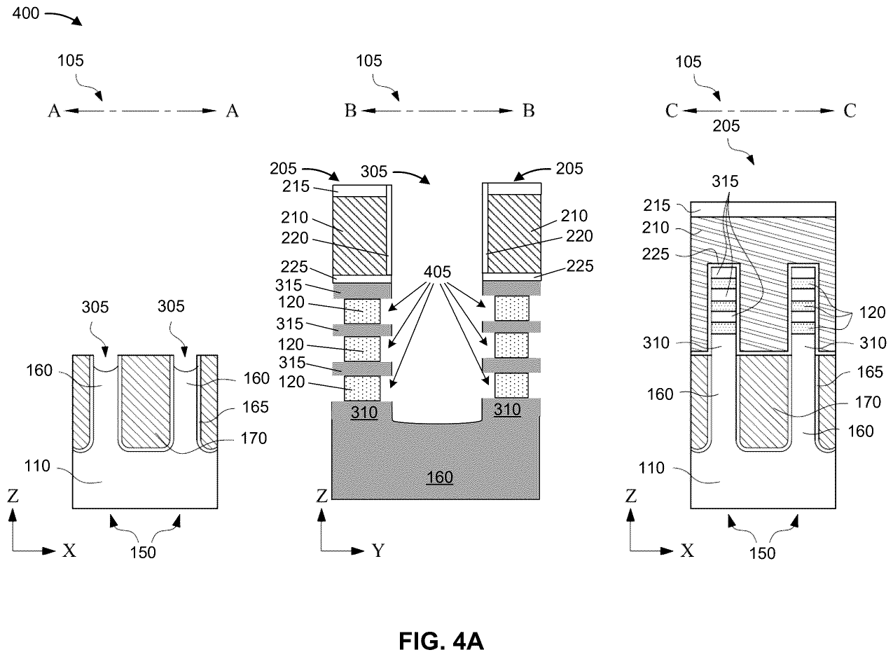

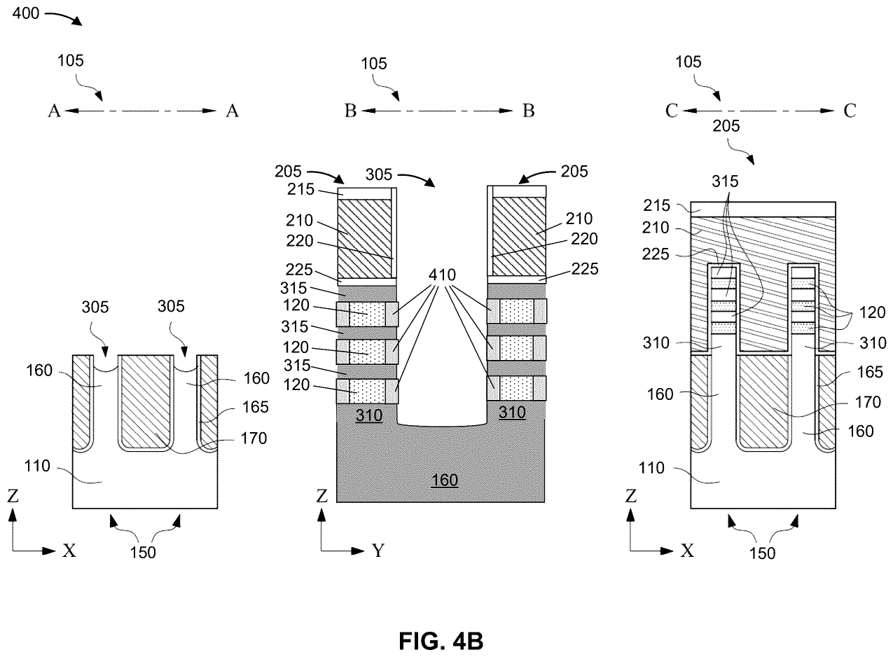

FIGS. 4A and 4B are diagrams of an example implementation 400 of an inner spacer formation process described herein. The example implementation 400 includes an example of forming inner spacers between ends of the nanostructure channels 315 that are exposed in the source/drain recesses 305. FIGS. 4A and 4B are illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 400 are performed after the processes described in connection with FIGS. 1A-3.

As shown in the cross-sectional plane A-A and in the cross-sectional plane B-B in FIG. 4A, the ends of the sacrificial nanostructure layers 120 may be laterally etched (e.g., in the x-direction that is approximately parallel to a length of the sacrificial nanostructure layers 120) in an etch operation, thereby forming cavities 405 between the ends of the nanostructure channels 315 that are exposed in the source/drain recesses 305. An etch tool may be used to perform a wet etch operation to selectively etch the ends of the sacrificial nanostructure layers 120 relative to the nanostructure channels 315 to form the cavities 405. Additionally and/or alternatively, another etch technique may be used, such as dry etching (e.g., gas-based etching).

As shown in the cross-sectional plane A-A and in the cross-sectional plane B-B in FIG. 4B, inner spacers (InSP) 410 are formed in the cavities 405 in the ends of the sacrificial nanostructure layers 120 that are exposed in the source/drain recesses 305. The inner spacer 410 may be included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. The inner spacers 410 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 410, a deposition tool may be used to deposit a layer of dielectric material in the cavities 405 and along the sidewalls and bottom surface of the source/drain recesses 305. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 410. Alternatively, the inner spacers 410 may be selectively formed on the ends of the sacrificial nanostructure layers 120 using precursors that selectively bond to the material of the sacrificial nanostructure layers 120 and not to the material of the fin portion 160 and the nanostructure channels 315.

As indicated above, FIGS. 4A and 4B are provided as an example. Other examples may differ from what is described with regard to FIGS. 4A and 4B.

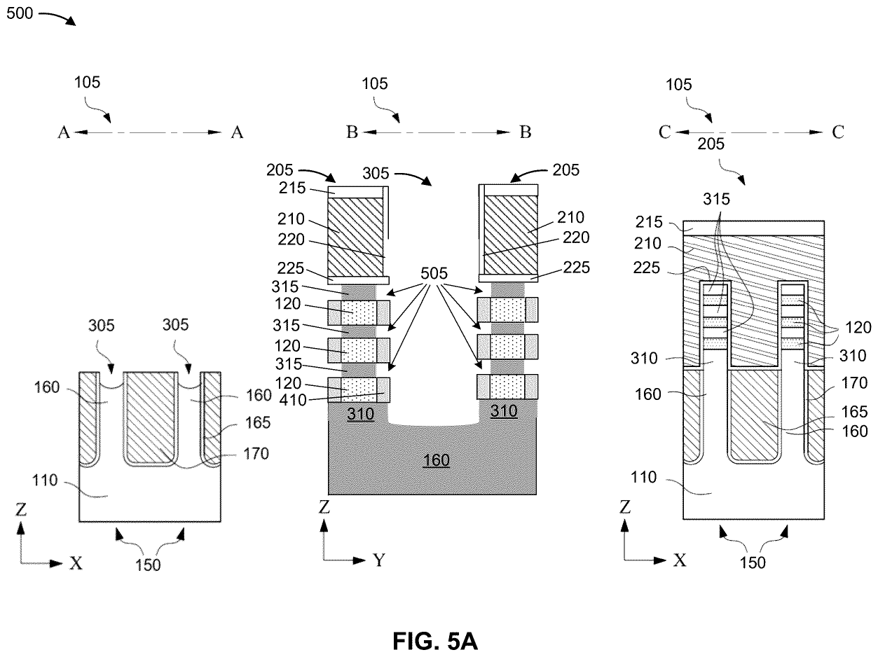

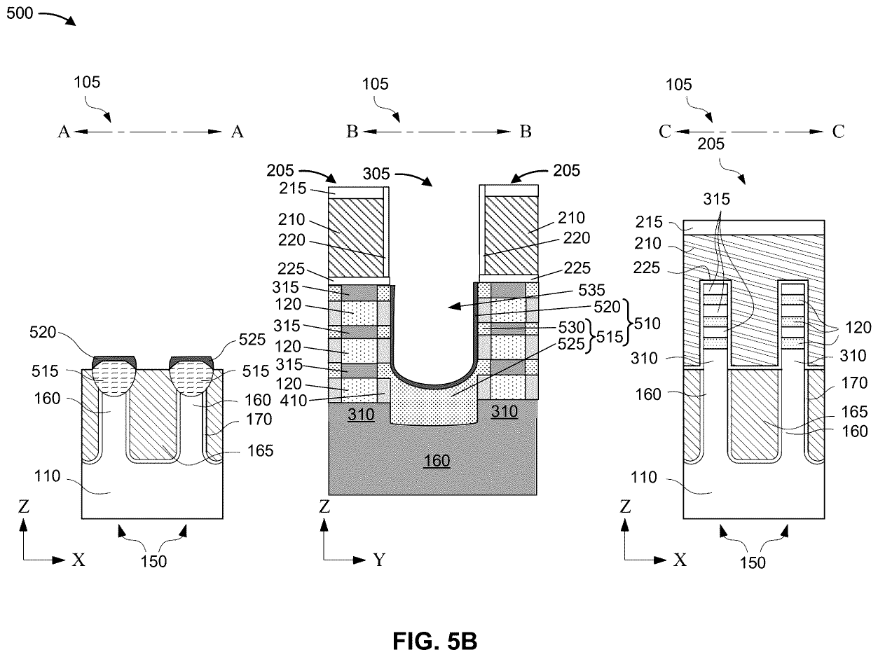

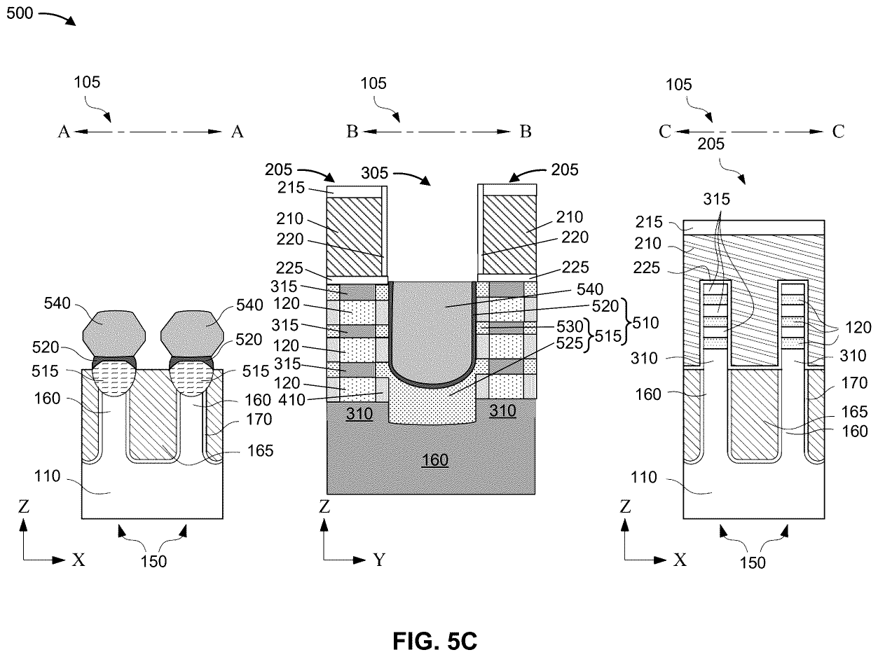

FIGS. 5A-5C are diagrams of an example implementation 500 of a source/drain region formation process described herein. The example implementation 500 includes an example of forming the source/drain regions of the nanostructure transistors of the semiconductor device 105. FIGS. 5A-5C are illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4B.

As shown in the cross-sectional plane A-A and in the cross-sectional plane B-B in FIG. 5A, the ends of the nanostructure channels 315 may be laterally etched (e.g., in the x-direction that is approximately parallel to a length of the sacrificial nanostructure layers 120) in an etch operation, thereby forming cavities 505 between vertically adjacent inner spacers 410. An etch tool may be used to perform a wet etch operation to selectively etch the ends of the nanostructure channels 315 relative to the sacrificial nanostructure layers to form the cavities 505. Additionally and/or alternatively, another etch technique may be used, such as dry etching (e.g., gas-based etching).

As shown in the cross-sectional plane A-A and the cross-sectional plane B-B in FIG. 5B, the source/drain recess 305 is partially filled with one or more epitaxial layers to form a source/drain region 510 in the source/drain recess 305. For example, a deposition tool may be used to deposit a first epitaxial layer 515 (sometimes referred to as an “L1”) at the bottom of the source/drain recess 305 and on recessed ends of the nanostructure channels 315 in the cavities 505. As another example, a deposition tool may deposit a second epitaxial layer 520 (sometimes referred to as an “L2”) in the source/drain recess 305. The second epitaxial layer 520 may fill in the remaining area in the source/drain recess 305 below the dummy gate structures 205 and may be in contact with the first epitaxial layer 515 and the inner spacers 410 that are still exposed in the source/drain recess 305.

“Source/drain region” may refer to a source or a drain, individually or collectively, depending upon the context. Source/drain regions 510 may be included on opposing sides of a dummy gate structure 205 such that the nanostructure channels 315 under the dummy gate structure 205 extend between, and are electrically coupled to, source/drain regions 510.

The first epitaxial layer 515 and the second epitaxial layer 520 of a source/drain region 510 may each include a semiconductor material such as silicon (Si), silicon germanium (SiGe), silicon arsenide (SiAs), silicon phosphorous (SiP), and/or another semiconductor material. The first epitaxial layer 515 and the second epitaxial layer 520 may each be doped with one or more types of dopants such as arsenic (As), phosphorous (P), and/or boron (B), among other examples.

For a p-type metal-oxide semiconductor (PMOS) nanostructure transistor, the first epitaxial layer 515 and the second epitaxial layer 520 of a source/drain region 510 may each include silicon germanium (SiGe) doped with boron (B). The germanium (Ge) concentration of the second epitaxial layer 520 may be greater than the germanium (Ge) concentration of the first epitaxial layer 515. For example, the germanium (Ge) concentration of the second epitaxial layer 520 may be included in a range of approximately 40% to approximately 60%, whereas the germanium (Ge) concentration of the first epitaxial layer 515 may be included in a range of approximately 10% to approximately 20%. However, other values and ranges are within the scope of the present disclosure. The boron (B) dopant concentration of the second epitaxial layer 520 and the boron (B) dopant concentration of the first epitaxial layer 515 may each be included in a range of approximately 5×10²⁰ to approximately 5×10²¹. However, other values and ranges are within the scope of the present disclosure.

For an n-type metal-oxide semiconductor (NMOS) nanostructure transistor, the first epitaxial layer 515 and the second epitaxial layer 520 of a source/drain region 510 may each include silicon (Si) doped with arsenic (As) and/or phosphorous (P), among other examples. The dopant concentration of the second epitaxial layer 520 may be greater than the dopant concentration of the first epitaxial layer 515. For example, the dopant concentration of the second epitaxial layer 520 may be included in a range of approximately 2×10²¹ to approximately 9×10²¹, whereas the dopant concentration of the first epitaxial layer 515 may be included in a range of approximately 1×10²⁰ to approximately 1×10²¹. However, other values and ranges are within the scope of the present disclosure.

The first epitaxial layer 515 and the second epitaxial layer 520 of a source/drain region 510 may each be epitaxially grown, deposited (e.g., using CVD, PVD, ALD), and/or formed using one or more other deposition techniques. For example, a deposition tool may epitaxially a grow merged region 525 of the first epitaxial layer 515 at the bottom of the source/drain recess 305. The merged region 525 may include a continuous layer of epitaxially-grown material that spans from the mesa regions 310 up to the ends of a bottom-most nanostructure channel 315.

As another example, a deposition tool may epitaxially grow a plurality of non-contiguous second epitaxial regions 530 of the first epitaxial layer 515 on the recessed ends of nanostructure channels 315 in the cavities 505 so that the non-contiguous second epitaxial regions 530 are located above the merged region 525. The non-contiguous second epitaxial regions 530 are regions of epitaxially-grown material that are not in contact with each other (e.g., because of being separated by the inner spacers 410), and that are not in contact with the merged region 525. The second epitaxial layer 520 may grow on portions of the inner spacers 410 that are exposed between the non-contiguous second epitaxial regions 530, and between the merged region 525 and the non-contiguous second epitaxial regions 530.

As further shown in FIG. 5B, the one or more epitaxial layers 515, 520 of the source/drain region 510 partially fill the source/drain recess 305, resulting in a cavity 535 extending into the source/drain region 510 from the top of the source/drain region 510. The cavity 535 is a hollow area within the source/drain region 510 that is not filled in with epitaxial material and is instead filled with air. The cavity 535 results from the second epitaxial layer 520 not fully merging and instead being formed along the sidewalls and the bottom surface of the area in the source/drain region 510 not filled in by the first epitaxial layer 515.

In some implementations, the bottom of the cavity 535 is located at a vertical (z-direction) position that corresponds to a vertical (z-direction) position of a bottom-most inner spacer 410. In some implementations, the bottom of the cavity 535 is located at a vertical (z-direction) position that corresponds to a vertical (z-direction) position of a bottom-most sacrificial nanostructure layer 120. In some implementations, the bottom of the cavity 535 is located at a vertical (z-direction) position that corresponds to a vertical (z-direction) position of a bottom-most nanostructure channel 315.

A shown in FIG. 5C, the cavity 535 in the source/drain region 510 is filled in to form a sacrificial plug 540 in the cavity 535. The sacrificial plug 540 may be a temporary structure that is subsequently removed and replaced with a portion of a source/drain contact that extends into the source/drain region 510. The sacrificial plug 540 enables subsequent processes to be performed prior to formation of the source/drain contact, such as a replacement gate process to replace the dummy gate structures 205 with metal gate structures.

In some implementations, the material of the sacrificial plug 540 is different from the material of the one or more epitaxial layers 515, 520 of the source/drain region 510, and/or is different from the material of the inner spacers 410. This enables an etchant to be used to selectively remove the sacrificial plug 540 with minimal to no removal of material from the one or more epitaxial layers 515, 520 of the source/drain region 510 and material from the inner spacers 410.

In some implementations, the material of the sacrificial plug 540 includes a semiconductor material that is different from the semiconductor material of the one or more epitaxial layers 515, 520. For example, the one or more epitaxial layers 515, 520 may include doped silicon and/or silicon germanium, and the sacrificial plug 540 may include germanium (Ge). The germanium concentration in the sacrificial plug 540 may be greater than the germanium concentration in the one or more epitaxial layers 515, 520. In some implementations, the material of the sacrificial plug 540 includes a metal-oxide material such as aluminum oxide (AlₓO_{y} such as Al₂O₃), hafnium oxide (HfOₓ such as HfO₂), and/or zirconium oxide (ZrOₓ such as ZrO₂), among other examples.

As indicated above, FIGS. 5A-5C are provided as an example. Other examples may differ from what is described with regard to FIGS. 5A-5C.

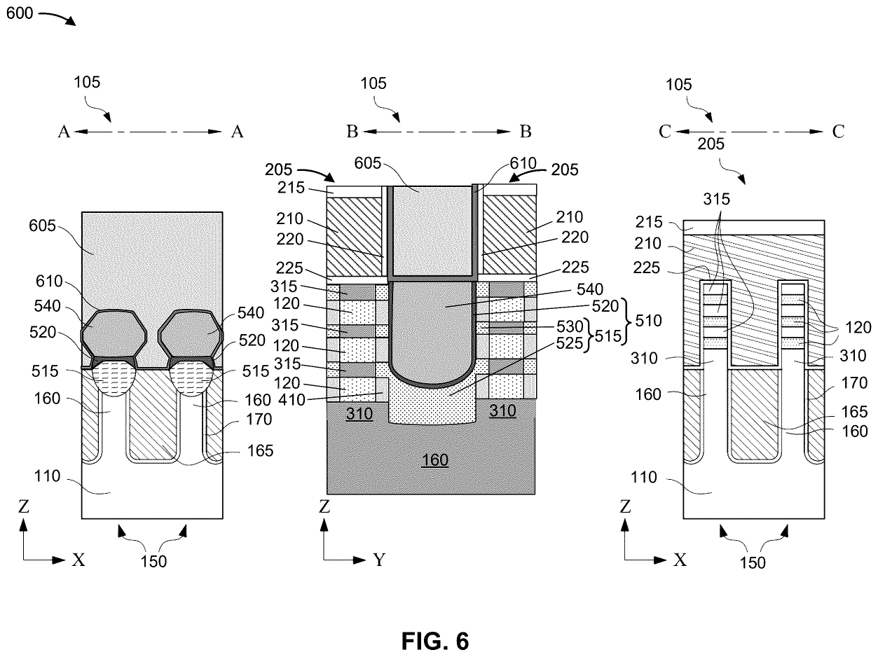

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 600 are performed after the processes described in connection with FIGS. 1A-5B.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of, and/or prevent, damage to the source/drain regions 510 during a replacement gate process to replace the dummy gate structures 205. The dielectric layer 605 may be referred to as an ILD zero (ILD0) layer or another ILD layer.

In some implementations, a contact etch stop layer (CESL) 610 is conformally deposited (e.g., by a deposition tool) over the source/drain regions 510 prior to formation of the dielectric layer 605. The dielectric layer 605 is then formed on the CESL 610. The CESL 610 may provide a mechanism to stop an etch process when forming contacts or vias for the source/drain regions 510.

The dielectric layer 605 may include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 605 includes an extreme low dielectric constant (ELK) dielectric material having a dielectric constant that is less than approximately 2.5. Examples of ELK dielectric materials include carbon doped silicon oxide (C-SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples. The dielectric layer 605 may be deposited using a deposition process, such as ALD, CVD, or another deposition technique.

The CESL 610 may be formed of a dielectric material having a different etch selectivity from adjacent layers or components. The CESL 610 may include or may be a nitrogen-containing material, a silicon-containing material, and/or a carbon-containing material. Furthermore, the CESL 610 may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL 610 may be deposited using a deposition process, such as ALD, CVD, or another deposition technique.

As indicated above, FIG. 6 is provided as an example. Other examples may differ from what is described with regard to FIG. 6.

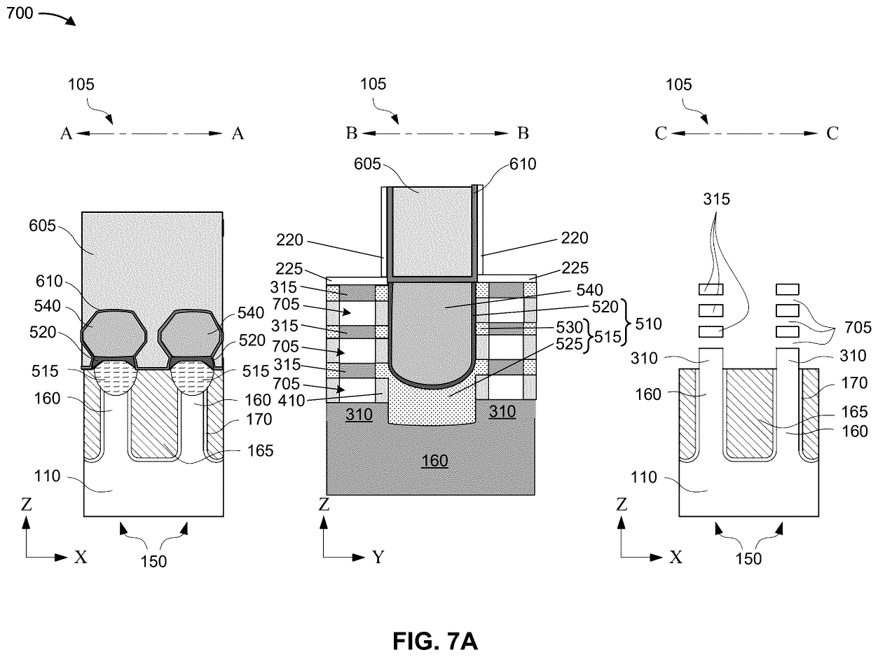

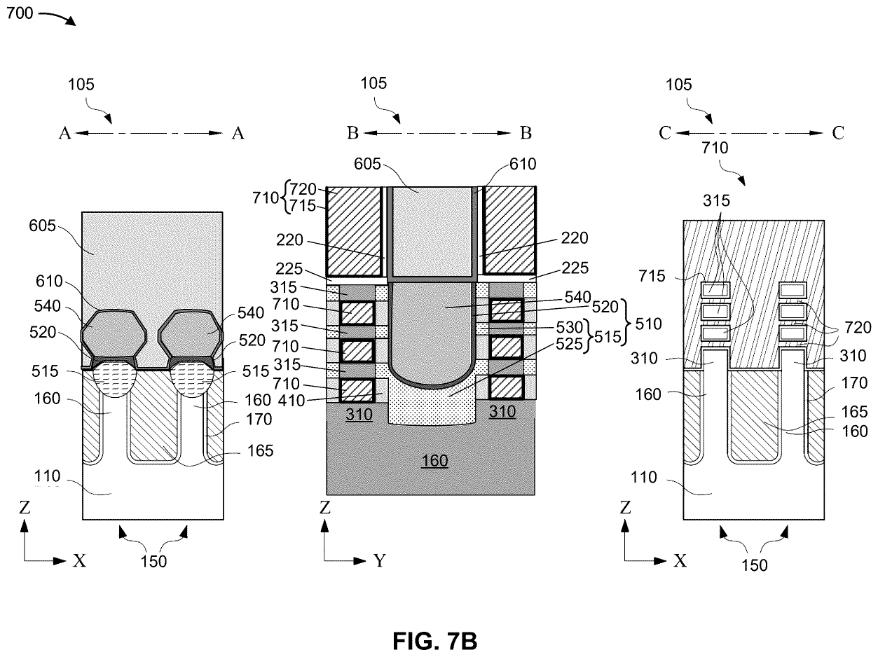

FIGS. 7A and 7B are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A and 7B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) in the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 410. The inner spacers 410 may function as etch stop layers in the etch operation to protect the source/drain regions 510 from being etched.

As shown in the cross-sectional plane B-B and the cross-sectional plane C-C in FIG. 7B, the replacement gate operation includes forming gate structures (e.g., replacement gate structures) 710 in the openings 705 between the source/drain regions 510 and between the inner spacers 410. In particular, the gate structures 710 fill the areas between and around the nanostructure channels 315 that were previously occupied by the sacrificial nanostructure layers 120 such that the gate structures 710 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 710 may also fill in the spaces that were previously occupied by the dummy gate structures 205. Portions of a gate structure 710 are formed in between pairs of nanostructure channels 315 in an alternating vertical arrangement. In other words, the semiconductor device 105 includes one or more vertical stacks of alternating nanostructure channels 315 and portions of a gate structure 710, as shown in FIG. 7B.

The gate structures 710 may each include a gate dielectric layer 715 and a metal gate electrode 720. A metal gate electrode 720 may include one or more metal materials such as tungsten (W), cobalt (Co), ruthenium (Ru), and/or titanium (Ti), among other examples. Additionally and/or alternatively, the gate structures 710 may each include one or more work function metal layers for tuning the work function of the metal gate electrode 720.

A gate dielectric layer 715 may be a conformal high-k dielectric liners that is deposited onto the nanostructure channels 315 and on sidewalls of the inner spacers 410 prior to formation of a gate electrode 720. The gate structures 710 may each include additional layers such as an interfacial layer, an adhesion layer, and/or a capping layer, among other examples. The gate dielectric layer 715 may include one or more high-k dielectric materials, such as a silicon nitride (SiₓN_{y}), a hafnium oxide (HfOₓ), a lanthanum oxide (LaOₓ), and/or another suitable high-k dielectric material.

Some source/drain regions 510 and gate structures 710 may be shared between two or more nanoscale transistors of the semiconductor device 105. In these implementations, one or more source/drain regions 510 and a gate structure 710 may be connected or coupled to a plurality of nanostructure channels 315, as shown in the example in FIG. 7B. This enables the plurality of nanostructure channels 315 to be controlled by a single gate structure 710 and a pair of source/drain regions 510.

As indicated above, FIGS. 7A and 7B are provided as an example. Other examples may differ from what is described with regard to FIGS. 7A and 7B.

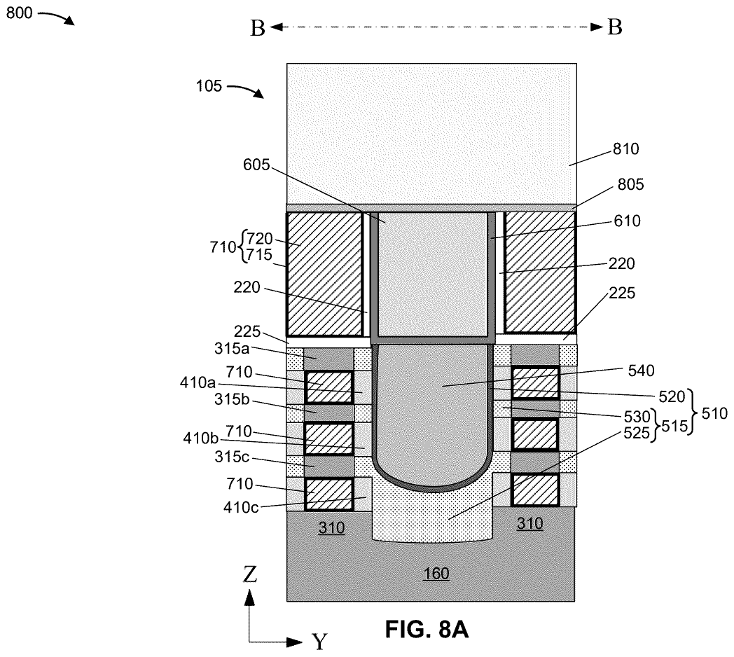

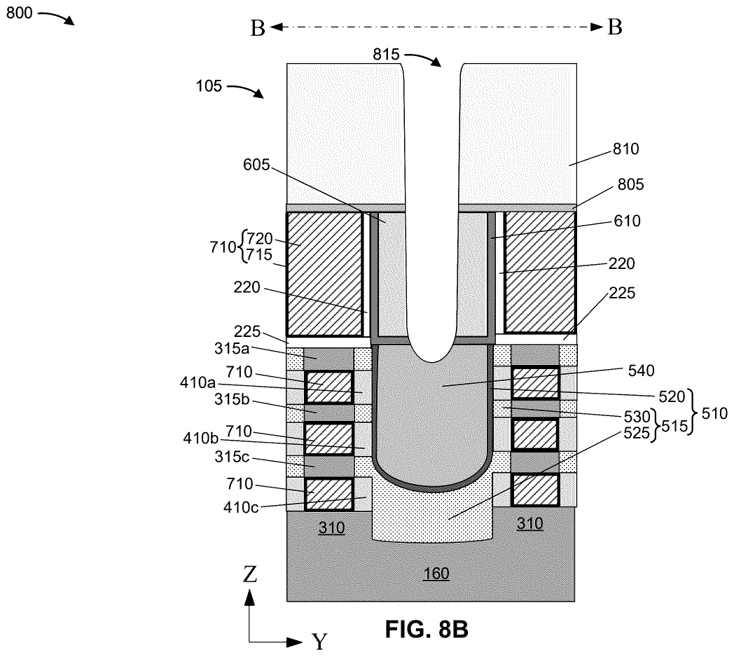

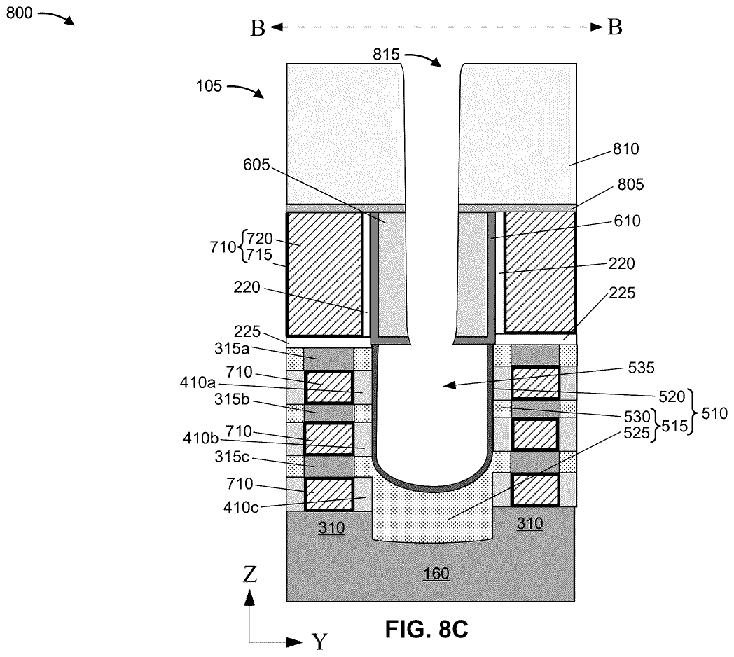

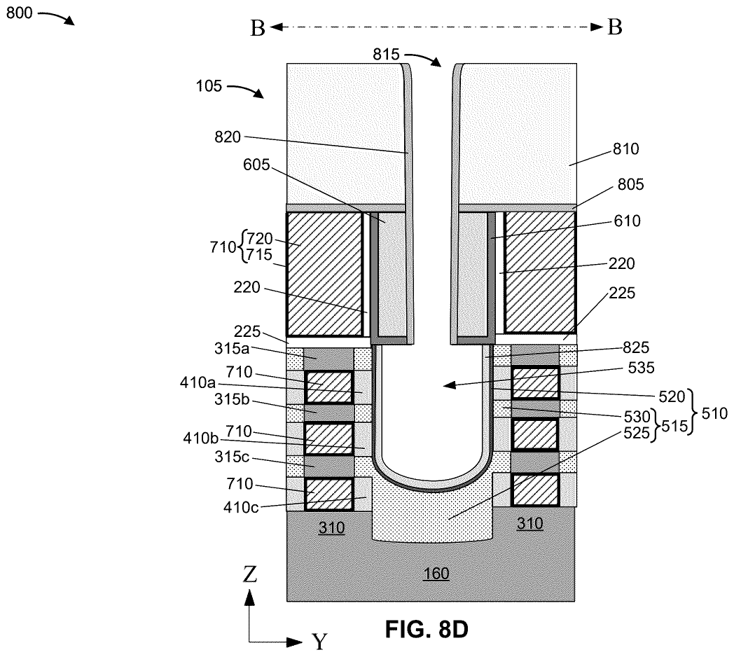

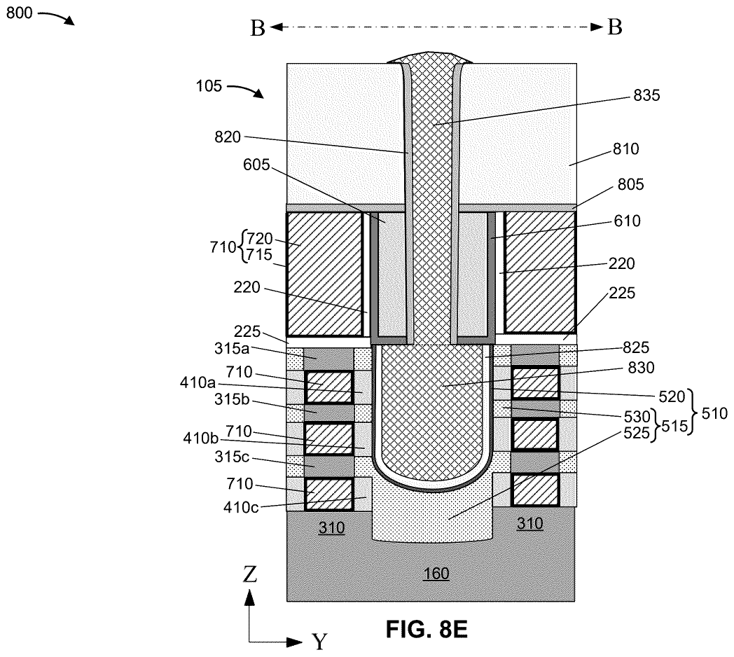

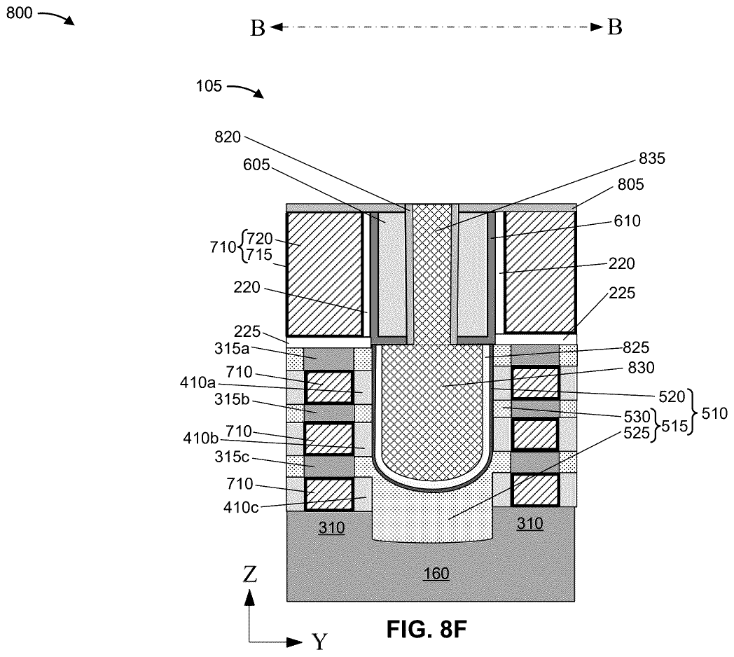

FIGS. 8A-8F are diagrams of an example implementation 800 of a source/drain contact formation process described herein. In particular, the example implementation 800 includes an example of forming a source/drain contact such that the source/drain contact is recessed within a source/drain region 510 of a nanostructure transistor of the semiconductor device 105 to achieve lower contact resistance and lower current crowding between the source/drain contact and the source/drain region 510. FIGS. 8A-8G are each illustrated from the perspective of the cross-sectional plane B-B in FIG. 2. In some implementations, the operations described in connection with the example implementation 800 are performed after the operations described in connection with FIGS. 1A-7B.

As shown in FIG. 8A, an etch stop layer (ESL) 805 may be formed above and/or on the dielectric layer 605, and above and/or on the top portions of the gate structures 710. Another dielectric layer 810 may be formed over and/or on the ESL 805.

The ESL 805 may include one or more dielectric materials, such as a silicon nitride (SiₓN_{y}), silicon carbon nitride (SiCN), carbon nitride (CN), silicon oxynitride (SiON), silicon carbon oxide (SiCO), or a combination thereof, among other examples. The dielectric layer 810 may be referred to as an ILD layer (e.g., an ILD1 layer), and may include one or more dielectric materials such as an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, the dielectric layer 810 includes an ELK dielectric material.

A deposition tool may be used to deposit the ESL 805 and/or the dielectric layer 810 using a PVD technique, an ALD technique, a CVD technique, and/or another suitable deposition technique. The ESL 805 and/or the dielectric layer 810 may be deposited in one or more deposition operations. In some implementations, a planarization tool may be used to perform a planarization operation (e.g., a CMP operation) to planarize the ESL 805 and/or the dielectric layer 810 after the ESL 805 and/or the dielectric layer 810 is deposited.

As shown in FIG. 8B, a contact recess 815 is formed through the dielectric layer 810, through the ESL 805, through the dielectric layer 605, and into the sacrificial plug 540 that is in the cavity 535 of the source/drain region 510.

A first etch operation using an etch tool is performed to form the contact recess 815. In some implementations, a pattern in a photoresist layer is used to form the contact recess 815. In these implementations, a deposition tool may be used to form the photoresist layer on the dielectric layer 810 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the dielectric layer 810, the ESL 805, the dielectric layer 605, and/or the sacrificial plug 540 based on the pattern to form the contact recess 815. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for forming the contact recess 815 on a pattern.

As shown in FIG. 8C, a second etch operation is performed (e.g., after the first etch operation described in connection with FIG. 8B) to remove the sacrificial plug 540 from the cavity 535 of the source/drain region 510. Removing the sacrificial plug 540 reveals the cavity 535. The second etch operation may be different from the first etch operation in that the first etch operation is performed using a first etchant, and the second etch operation is performed using a second etchant that is different than the first etchant. For example, the first etch operation may be performed using a plasma-based etchant and the second etch operation may be performed using a gas-based etchant or a wet etchant.

Different etchants may be used for the first etch operation and the second etch operation to achieve different etch selectivity for the first etch operation and the second etch operation. For example, the first etchant used in the first etch operation may be selected to achieve a low etch selectivity between the dielectric layers above the source/drain region 510 (e.g., the dielectric layer 605, the ESL 805, the dielectric layer 810) and the material of the sacrificial plug 540. This enables the contact recess 815 to be formed through the dielectric layer 605, the ESL 805, the dielectric layer 810, and into the sacrificial plug 540 in the first etch operation.

For the second etch operation, the second etchant may be selected to achieve a high etch selectivity between the dielectric layers above the source/drain region 510 (e.g., the dielectric layer 605, the ESL 805, the dielectric layer 810) and the material of the sacrificial plug 540, as well as between the material of the sacrificial plug 540 and the one or more epitaxial layers 515, 520 (e.g., the semiconductor material of the one or more epitaxial layers 515, 520) of the source/drain region 510. For example, the one or more epitaxial layers 515, 520 of the source/drain region 510 may include doped silicon, the material of the sacrificial plug 540 may include germanium, and a wet etchant such as a mixed solution including hydrogen peroxide (H₂O₂), acetic acid (CH₃COOH), and/or hydrogen fluoride (HF), may be used to etch the sacrificial plug 540. As another example, the one or more epitaxial layers 515, 520 of the source/drain region 510 may include doped silicon, the material of the sacrificial plug 540 may include a metal-oxide material, and an etchant such as hydrogen fluoride (HF), phosphoric acid (H₃PO₄), and/or hydrochloric acid (HCl) may be used to etch the sacrificial plug 540.

In some implementations, some intermixing between the sacrificial plug 540 and the second epitaxial layer 520 of the source/drain region 510 occurs. In these implementations, some material of the second epitaxial layer 520 may be removed during the second etch operation.

As shown in FIG. 8C, the bottom of the cavity 535 may be located at a vertical (z-direction) position that corresponds to a vertical (z-direction) position of a top of a bottom-most inner spacer 410 (e.g., an inner spacer 410c among vertically-arranged inner spacers 410a-410c). In some implementations, the bottom of the cavity 535 is located at a vertical (z-direction) position that corresponds to a vertical (z-direction) position of a bottom of a bottom-most nanostructure channel 315 (e.g., a nanostructure channel 315c among vertically-arranged nanostructure channels 315a-315c).

As shown in FIG. 8D, sidewall liners 820 may be formed on portions of the sidewalls of the contact recess 815 above the cavity 535 in the source/drain region 510. The sidewall liners 820 may be formed as protective liners that protect the sidewalls of the contact recess 815 from being etched (and therefore, the lateral width of the contact recess 815 from being widened) during a second etch operation that is to be subsequently performed to increase the depth of the contact recess 815. Additionally and/or alternatively, the sidewall liners 820 may include barrier liners that are included to reduce and/or prevent diffusion of material from a source/drain contact (e.g., that is to be formed in the contact recess 815) into the surrounding dielectric layers.

The sidewall liners 820 may include one or more dielectric materials. For example, the sidewall liners 820 may include a silicon nitride (SiₓN_{y} such as Si₃N₄), a silicon oxynitride (SiON), a silicon oxycarbide (SiOC), a silicon oxycarbonitride (SiOCN), and/or another suitable dielectric material.

To form the sidewall liners 820, a conformal layer of dielectric material may be deposited on the sidewalls of the contact recess 815 (e.g., corresponding to exposed surfaces of the dielectric layer 605, exposed surfaces of the ESL 805, and exposed surfaces of the dielectric layer 810) and on the bottom surface of the contact recess 815 (e.g., corresponding to the exposed surfaces of the second epitaxial layer 520 of the source/drain region 510). A deposition tool may be used to deposit the conformal layer of dielectric material using a deposition technique such as ALD and/or CVD, among other examples.

An etch tool may be used to trim the portion of the conformal layer of dielectric material located on the bottom surface of the contact recess 815 so that the conformal layer of dielectric material is removed from the surface of the second epitaxial layer 520 of the source/drain region 510. In this way, the surface of the second epitaxial layer 520 of the source/drain region 510 is exposed again through the contact recess 815, and the remaining portions of the conformal layer of dielectric material located on the sidewalls of the contact recess 815 correspond to the sidewall liners 820.

An anisotropic etch technique may be used to trim the portion of the conformal layer of dielectric material located on the bottom surface of the contact recess 815 so that the portions of the conformal layer of dielectric material located on the sidewalls of the contact recess 815 remain as the sidewall liners 820. For example, a plasma-based etch technique (such as a reactive ion etch (RIE) technique) may be used to perform a primarily vertical (e.g., z-direction) etch to trim the conformal layer of dielectric material. However, other etch techniques are within the scope of the present disclosure.

As further shown in FIG. 8D, a metal silicide layer 825 is formed at the bottom of the cavity 535 in the source/drain region 510. In particular, the metal silicide layer 825 may be formed from the surface of the source/drain region 510 (e.g., the surface of the second epitaxial layer 520 of the source/drain region 510) exposed in the cavity 535. To form the metal silicide layer 825, a salicidation process may be performed. The salicidation process includes using a deposition tool to deposit (e.g., by CVD, ALD, PVD, and/or electroplating) a layer of metal material on the surface of the second epitaxial layer 520 of the source/drain region 510 exposed in the cavity 535. An annealing operation may be performed to increase the temperature of the layer of metal material and the surface of the second epitaxial layer 520 of the source/drain region 510 exposed in the cavity 535 to cause the metal material to diffuse into the surface of the second epitaxial layer 520 of the source/drain region 510 exposed in the cavity 535. This results in formation of the metal silicide layer 825. In other words, the surface of the second epitaxial layer 520 of the source/drain region 510 exposed in the cavity 535 may be transformed from a semiconductor surface to a metal silicide surface.

In some implementations, the layer of metal material includes titanium (Ti) and the metal silicide layer 825 includes titanium silicide (TiSi). In some implementations, the layer of metal material includes ruthenium (Ru) and the metal silicide layer 825 includes ruthenium silicide (RuSi). In some implementations, the layer of metal material includes cobalt (Co) and the metal silicide layer 825 includes cobalt silicide (CoSi).

The metal silicide layer 825 may be formed to a thickness that is included in a range of approximately 3.5 nanometers to approximately 7 nanometers. However, other values and ranges are within the scope of the present disclosure.

In some implementations, the material of the second epitaxial layer 520 remaining after the second etch operation described in connection with FIG. 8C is fully consumed during the salicidation process to form the metal silicide layer 825. In other words, the remaining material of the second epitaxial layer 520 may be fully converted to the metal silicide layer 825 during the salicidation process such that the second epitaxial layer 520 no longer remains in the source/drain region 510.

As shown in FIG. 8E, the remaining area in the cavity 535, and the contact recess 815, are filled in with electrically conductive material. The electrically conductive material deposited in the cavity 535 of the source/drain region 510 corresponds to a metal core 830 of the source/drain region 510. Thus, the source/drain region 510 may include the metal core 830 that is laterally surrounded by the one or more epitaxial layers 515, 520 and the metal silicide layer 825.

Alternatively, the electrically conductive material deposited in the cavity 535 of the source/drain region 510 may correspond to a bottom portion of a source/drain contact 835 that is recessed within the source/drain region 510. The source/drain contact 835 extends through the dielectric layer 810, through the ESL 805, and through the dielectric layer 605. The sidewall liners 820 may be located between the source/drain contact 835 and the dielectric layer 605, between the source/drain contact 835 and the ESL 805, and/or between the source/drain contact 835 and the dielectric layer 810.

The metal core 830 and/or the source/drain contact 835 may include a contact plug, a via, a conductive column, a conductive pillar, and/or another type of conductive structure that is elongated in the z-direction in the semiconductor device 105. The metal core 830 and/or the source/drain contact 835 may include one or more electrically conductive materials such as tungsten (W), ruthenium (Ru), cobalt (Co), titanium (Ti), molybdenum (Mo), copper (Cu), and/or aluminum (Al), among other examples. A deposition tool may be used to deposit the material of the metal core 830 and/or the source/drain contact 835 in the cavity 535 and in the contact recess 815 using a CVD technique, an ALD technique, a PVD technique, an electroplating technique, and/or another suitable deposition technique.

In this way, the metal core 830 (or the bottom portion of the source/drain contact 835) and the metal silicide layer 825 extend into the source/drain region 510 to a depth that is below a middle nanostructure channel 315 (e.g., a nanostructure channel 315b). The increased depth to which the metal core 830 and/or the source/drain contact 835 is recessed within the source/drain region 510 in the semiconductor device 105 may reduce the contact resistance between the source/drain contact 835 and the source/drain region 510 because of the increased contact area between the source/drain contact 835 and the source/drain region 510. The increased contact area is achieved in that the metal core 830 and/or the source/drain contact 835 being recessed within the source/drain region 510 results in portions of the sidewalls of the metal core 830 and/or the source/drain contact 835 being in contact with the source/drain region 510, in addition to the bottom surface of the metal core 830 and/or the source/drain contact 835 being in contact with the source/drain region 510.

Additionally and/or alternatively, the increased depth to which the metal core 830 and/or the source/drain contact 835 is recessed within the source/drain region 510 in the semiconductor device 105 may reduce current crowding in the source/drain region 510 because the metal core 830 and/or the source/drain contact 835 extends alongside the top-most nanostructure channels (e.g., the nanostructure channels 315a), alongside the middle nanostructure channels (e.g., the nanostructure channels 315b), and in some implementations, alongside the bottom-most nanostructure channels (e.g., the nanostructure channels 315c). This provides for a more direct lateral path of travel for charge carriers between the source/drain contact 835 and the nanostructure channels 315 through the source/drain region 510 (e.g., as opposed to the charge carriers having to travel vertically in addition to horizontally to reach the nanostructure channels 315a, 315b, and/or 315c if the source/drain contact 835 terminated at the top of the source/drain region 510).

As shown in FIG. 8F, a planarization tool may be used to perform a planarization operation (e.g., a CMP operation) to planarize the semiconductor device 105. In the planarization operation, excess material of the source/drain contact 835 is removed, and the dielectric layer 810 may be removed. The planarization operation may be stopped once the ESL 805 is reached.

In this way, the semiconductor device 105 may include a plurality of nanostructure channels 315 arranged in a first direction (e.g., the nanostructure channels 315a-315c arranged in the z-direction) in the semiconductor device 105. The semiconductor device 105 may include a gate structure 710 wrapping around the plurality of nanostructure channels 315. The semiconductor device 105 may include a source/drain region 510 adjacent to (e.g., laterally adjacent to) a side of the gate structure 710 and laterally adjacent to ends of the plurality of nanostructure channels 315 in a second direction (e.g., in the y-direction) that is approximately perpendicular to the first direction. The semiconductor device 105 may include a plurality of inner spacers 410 (e.g., inner spacers 410a-410c arranged in the z-direction) between the source/drain region 510 and the gate structure 710. The semiconductor device 105 may include a source/drain contact 835 extending (e.g., in the z-direction) into the source/drain region 510 to a depth that is lower than top-most inner spacers (e.g., the inner spacers 410a) and that is lower than the top-most nanostructure channels (e.g., the nanostructure channels 315a). A bottom portion of the source/drain contact 835 may correspond to a metal core 830 of the source/drain region 510, and the metal core 830 may be laterally surrounded by one or more epitaxial layers 515, 520 and a metal silicide layer 825 of the source/drain region 510.

The source/drain contact 835 may electrically connect the source/drain region 510 to an interconnect layer (e.g., a back end region or a back end of line (BEOL) region) of the semiconductor device 105. This enables electrical signals and/or electrical power to be routed between one or more conductive structures (not shown) in the interconnect layer and the source/drain region 510 through the source/drain contact 835.

As indicated above, FIGS. 8A-8F are provided as an example. Other examples may differ from what is described with regard to FIGS. 8A-8F.

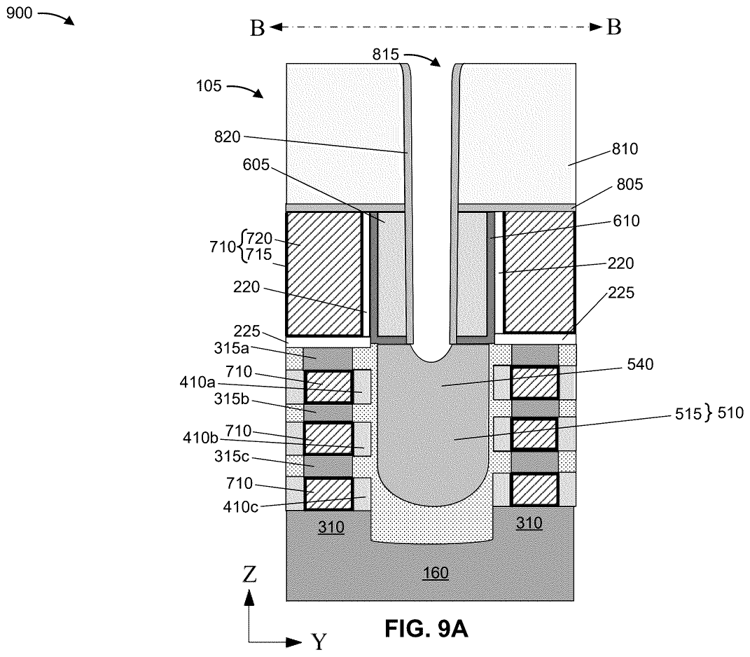

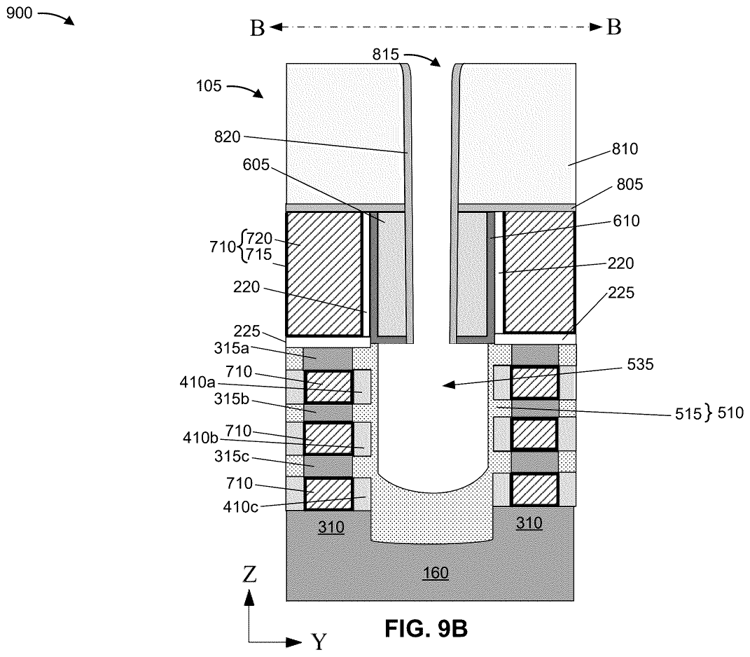

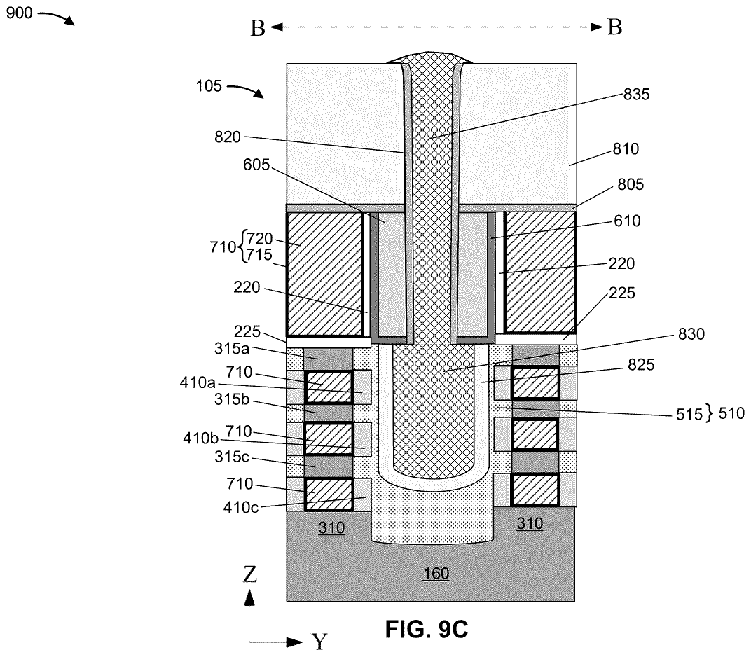

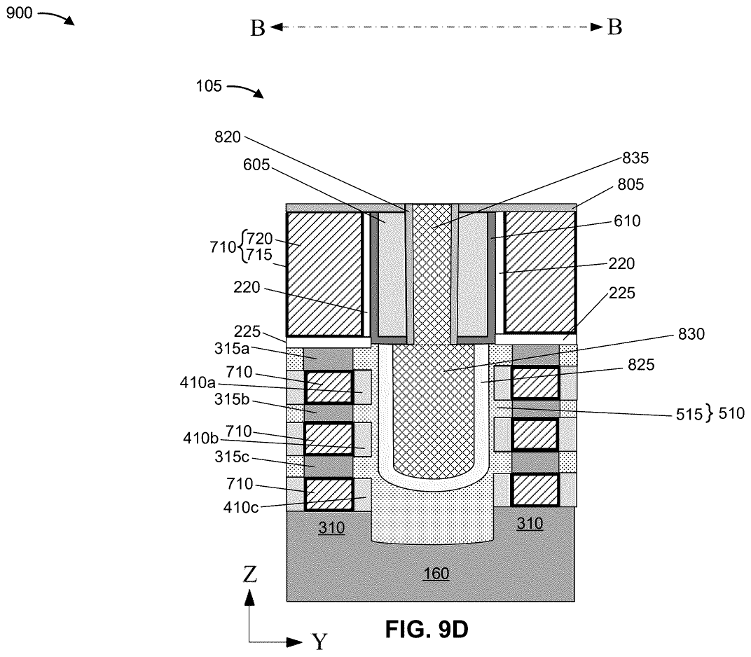

FIGS. 9A-9D are diagrams of an example implementation 900 of forming the semiconductor device 105 described herein. The example implementation 900 is similar to the processes described in connection with FIGS. 1A-8G, except that the second epitaxial layer 520 may be omitted.

As shown in FIG. 9A, the sacrificial plug 540 may be formed in the cavity 535 such that the sacrificial plug 540 is in contact with the first epitaxial layer 515. The first epitaxial layer 515 may be formed such that the first epitaxial layer 515 is merged along the sidewalls and the bottom surface of the source/drain region 510, but still non-merged in the center area of the source/drain region 510 so that the cavity 535 is formed.

As shown in FIG. 9B, the sacrificial plug 540 may be subsequently removed through the contact recess 815 after the replacement gate process of FIGS. 7A and 7B is performed. This results in the cavity 535 in the source/drain region 510 being revealed. The sacrificial plug 540 may be removed in a similar manner as described in connection with FIG. 8C. The sidewall liners 820 may be formed on the sidewalls of the contact recess 815 above the cavity 535 in a similar manner as described in connection with FIG. 8D.

As shown in FIG. 9C, the metal silicide layer 825 may be formed in the cavity 535. The metal silicide layer 825 may be formed in a similar manner as described in connection with FIG. 8D, except that a portion of the material of the first epitaxial layer 515 is consumed to form the metal silicide layer 825. Thus, the metal silicide layer 825 may be formed from material of the first epitaxial layer 515 in the example implementation 900.

As further shown in FIG. 9C, the metal core 830 of the source/drain region 510 is formed on the metal silicide layer 825 in the cavity 535, and the remaining area in the contact recess 815 is filled in with material of the source/drain contact 835. The metal core 830 and the source/drain contact 835 may be formed in a similar manner as described in connection with FIG. 8E.

As shown in FIG. 9D, a planarization tool may be used to perform a planarization operation (e.g., a CMP operation) to planarize the semiconductor device 105. In the planarization operation, excess material of the source/drain contact 835 is removed, and the dielectric layer 810 may be removed. The planarization operation may be stopped once the ESL 805 is reached.

As indicated above, FIGS. 9A-9D are provided as an example. Other examples may differ from what is described with regard to FIGS. 9A-9D.

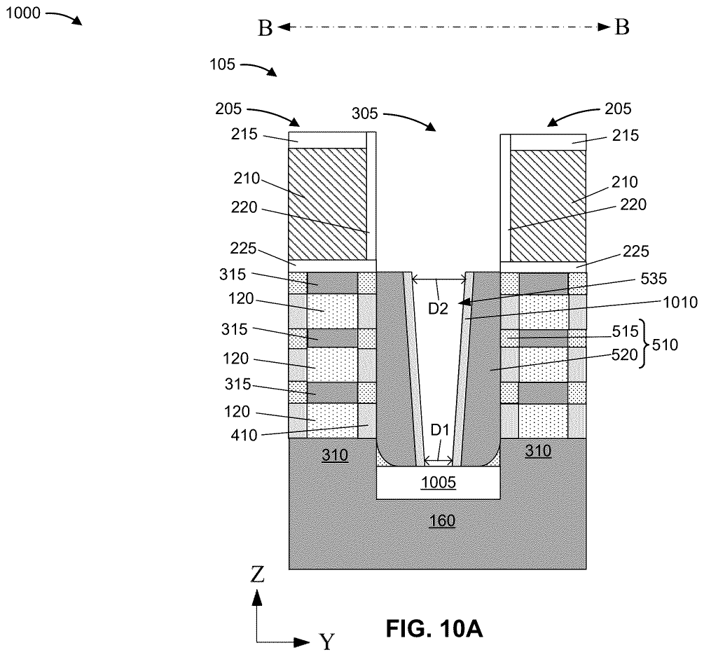

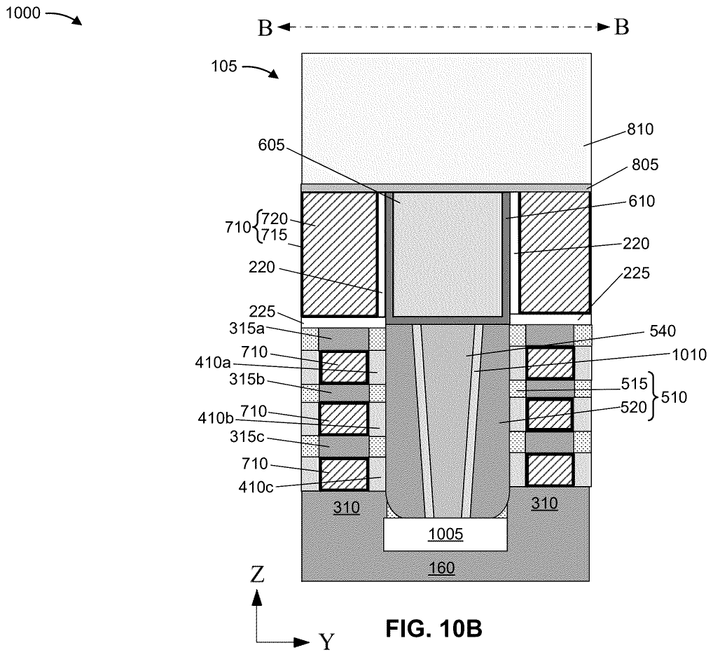

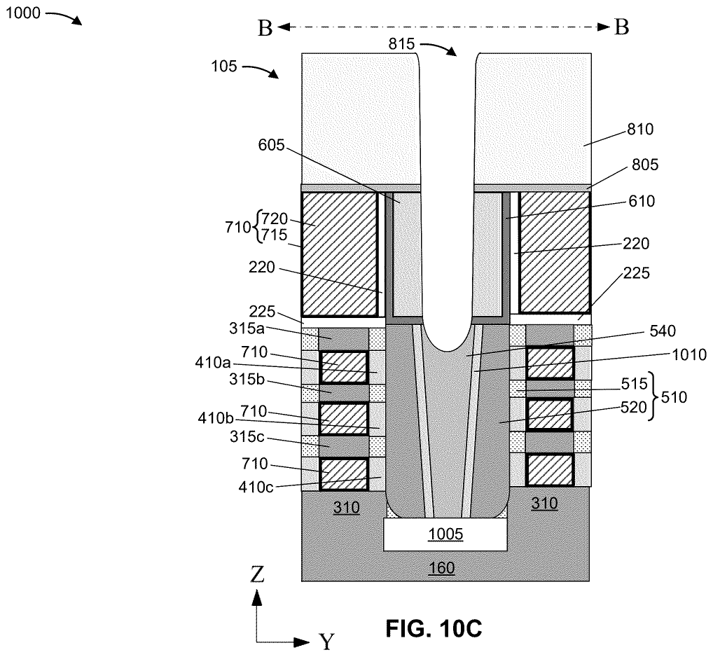

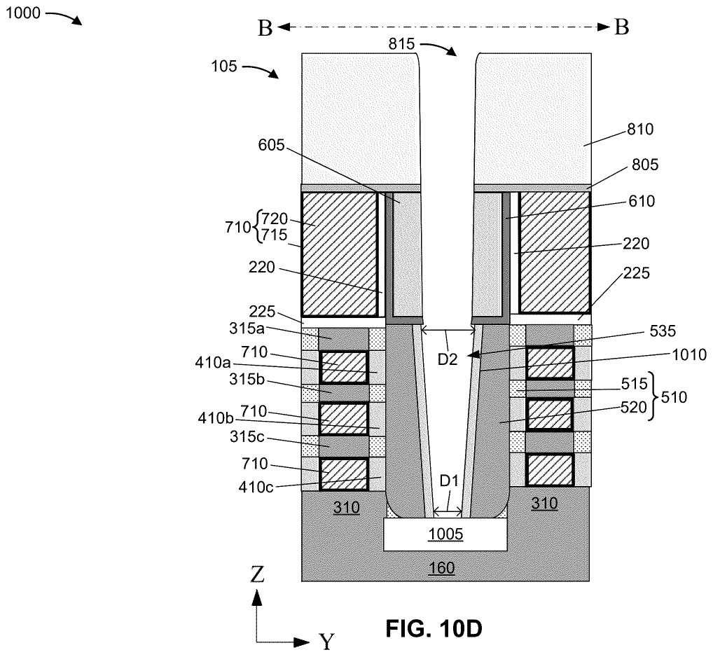

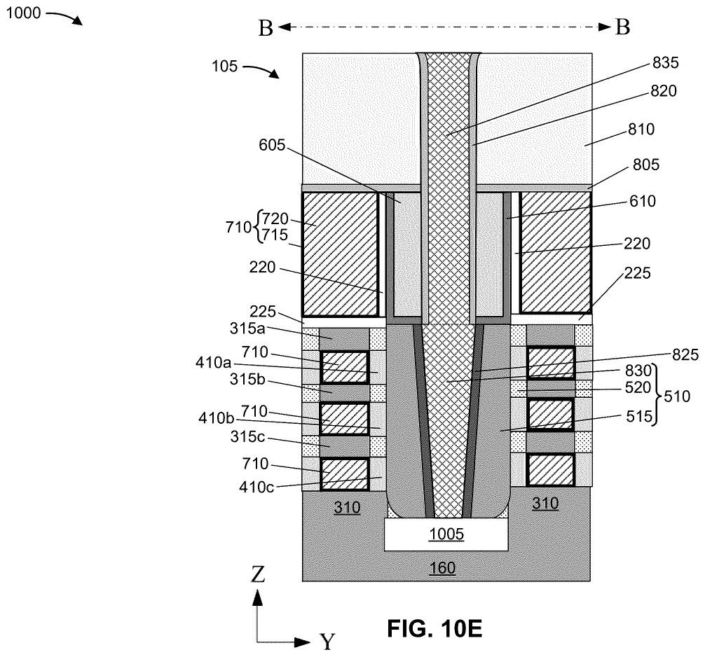

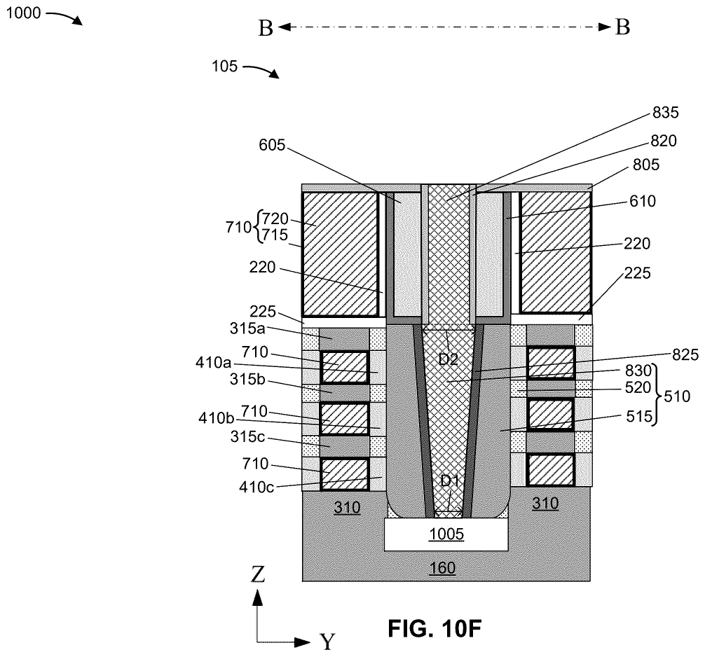

FIGS. 10A-10F are diagrams of an example implementation 1000 of forming the semiconductor device 105 described herein. The example implementation 1000 is similar to the processes described in connection with FIGS. 1A-8G. However, and as shown in FIG. 10A, the cavity 535 extends vertically fully through the source/drain region 510 in the example implementation 1000. In other words, the one or more epitaxial layers 515, 520 of the source/drain region 510 are not merged at the bottom of the source/drain recess 305, resulting in the source/drain region 510 having a hollow core.

As shown in FIG. 10A, in some implementations, a bottom isolation layer 1005 (sometimes referred to as a flexible bottom insulator) may be formed at the bottom of the source/drain recess 305. The bottom isolation layer 1005 may prevent, minimize, and/or reduce bottom parasitic transistor leakage current while also reducing parasitic capacitance (e.g., effective capacitance Ceff) in the semiconductor device.

Moreover, the bottom isolation layer 1005 may include one or more materials that inhibit epitaxial growth of the one or more epitaxial layers 515, 520 of the source/drain region 510 on the bottom of the source/drain recess 305. For example, the bottom isolation layer 1005 may include a silicon nitride (SiₓN_{y} such as Si₃N₄), silicon oxycarbide (SiOC), silicon oxycarbonitride (SiOCN), and/or silicon carbonitride (SiCN), among other examples. Since the bottom isolation layer 1005 inhibits epitaxial growth of the one or more epitaxial layers 515, 520 of the source/drain region 510 on the bottom of the source/drain recess 305, the epitaxial growth of the one or more epitaxial layers 515, 520 may be primarily on the sidewalls of the source/drain region 510. For example, a deposition tool may be used to perform an epitaxial deposition operation in which material of the first epitaxial layer 515 grows on the exposed ends of the nanostructure channels 315 and on the exposed ends of the mesa regions 310 in the source/drain recess 305. The exposed ends of the nanostructure channels 315 and on the exposed ends of the mesa regions 310 function as a growth substrate for the first epitaxial layer 515. A deposition tool may be used to perform another epitaxial deposition operation in which material of the second epitaxial layer 520 grows on the first epitaxial layer 515 so that the epitaxial material of the second epitaxial layer 520 merges together to form a continuous layer of epitaxial material on the sidewalls of the source/drain recess 305.

A deposition tool may be used to deposit the bottom isolation layer 1005 using a PVD technique, an ALD technique, a CVD technique, an oxidation technique, and/or another suitable deposition technique. In some embodiments, the bottom isolation layer 1005 may be formed to a thickness that is included in a range of approximately 1 nanometer to about 5 nanometers. However, other values and ranges are within the scope of the present disclosure.

As further shown in FIG. 10A, a capping layer 1010 may be formed on the second epitaxial layer 520. The capping layer 1010 may include an undoped semiconductor material such as undoped silicon (Si). In some implementations, the capping layer 1010 includes amorphous undoped silicon (Si), and is formed so that the capping layer 1010 can be consumed to form a metal silicide layer 825 on the second epitaxial layer 520 (e.g., instead of, or in addition to, consuming material of the second epitaxial layer 520 to form the metal silicide layer 825). A deposition tool may be used to perform an epitaxial deposition operation in which material of the capping layer 1010 grows on the second epitaxial layer 520.

As further shown in FIG. 10A, the cavity 535 (e.g., the hollow core) of the source/drain region 510 may have a tapered cross-sectional profile in which a bottom width (e.g., in the y-direction) of the cavity 535 (indicated in FIG. 10A as a dimension D1) is less than a top width (e.g., in the y-direction) of the cavity 535 (indicated in FIG. 10A as a dimension D2). The width of the cavity 535 may decrease from the top of the cavity 535 to the bottom of the cavity 535. In some implementations, the tapered cross-sectional profile of the cavity 535 results from the source/drain recess 305 having a similar tapered cross-sectional profile. In some implementations, the tapered cross-sectional profile of the cavity 535 results from epitaxial growth of the one or more epitaxial layers 515, 520 of the source/drain region 510 being greater at the bottom of the source/drain region 510 than at the top of the source/drain region 510.

As shown in FIG. 10B, the sacrificial plug 540 may be formed in the cavity 535 such that the sacrificial plug 540 is in contact with the capping layer 1010. Moreover, the dielectric layer 605, the ESL 805, and the dielectric layer 810 may be formed above the source/drain region 510. In addition, a replacement gate process may be performed in a similar manner as described in connection with FIGS. 7A and 7B to replace the dummy gate structures 205 and the sacrificial nanostructure layers 120 with the metal gate structures 710.

As shown in FIG. 10C, the contact recess 815 may be formed through the dielectric layer 810, through the ESL 805, through the dielectric layer 605, and to the sacrificial plug 540 after the replacement gate process of FIGS. 7A and 7B is formed. The contact recess 815 may be formed in a similar manner as described in connection with FIG. 8B.

As shown in FIG. 10D, the sacrificial plug 540 may be subsequently removed through the contact recess 815. This results in the cavity 535 (e.g., the hollow core) in the source/drain region 510 being revealed. The sacrificial plug 540 may be removed in a similar manner as described in connection with FIG. 8C.

As shown in FIG. 10E, the sidewall liners 820 may be formed on the sidewalls of the contact recess 815 above the cavity 535 in a similar manner as described in connection with FIG. 8D.

As further shown in FIG. 10E, the metal silicide layer 825 may be formed in the cavity 535. The metal silicide layer 825 may be formed in a similar manner as described in connection with FIG. 8D, except that the capping layer 1010 is consumed to form the metal silicide layer 825, with minimal to no material of the second epitaxial layer 520 being consumed to form the metal silicide layer 825. Since the one or more epitaxial layers 515, 520 of the source/drain region 510 are not merged at the bottom of the cavity 535, the metal silicide layer 825 may extend from a top of the cavity 535 to a bottom of the cavity 535 to the underlying bottom isolation layer 1005.

As further shown in FIG. 10E, the metal core 830 of the source/drain region 510 is formed on the metal silicide layer 825 in the cavity 535, and the remaining area in the contact recess 815 is filled in with material of the source/drain contact 835. The metal core 830 and the source/drain contact 835 may be formed in a similar manner as described in connection with FIG. 8E.

However, since the one or more epitaxial layers 515, 520 of the source/drain region 510 are not merged at the bottom of the cavity 535, the metal core 830 extends from a top of the cavity 535 to a bottom of the cavity 535 to the underlying bottom isolation layer 1005 in the example implementation 1000. In other words, the metal core 830 may fully extend through the source/drain region 510 from the top of the source/drain region 510 to the bottom of the source/drain region 510. Thus, the bottom of the metal core 830 may be located at a vertical (z-direction) position that is lower in the semiconductor device 105 than the bottom-most nanostructure channels 315 (e.g. nanostructure channels 315c), and that is lower in the semiconductor device 105 than the bottom-most inner spacers 410 (e.g. inner spacers 410c). In some implementations, the bottom of the metal core 830 may be located at a vertical (z-direction) position corresponding to the mesa regions 310 (or the bottoms of the mesa regions 310).

As shown in FIG. 10F, a planarization tool may be used to perform a planarization operation (e.g., a CMP operation) to planarize the semiconductor device 105. In the planarization operation, excess material of the source/drain contact 835 is removed, and the dielectric layer 810 may be removed. The planarization operation may be stopped once the ESL 805 is reached.

As further shown in FIG. 10F, the metal core 830 of the source/drain region 510 may have a tapered cross-sectional profile in which a bottom width (e.g., in the y-direction) of the metal core 830 (dimension D1) is less than a top width (e.g., in the y-direction) of the metal core 830 (dimension D2). The width of the metal core 830 may decrease from the top of the source/drain region 510 to the bottom of the source/drain region 510 in that the metal core 830 may conform to the profile of the cavity 535.

As indicated above, FIGS. 10A-10F are provided as an example. Other examples may differ from what is described with regard to FIGS. 10A-10F.

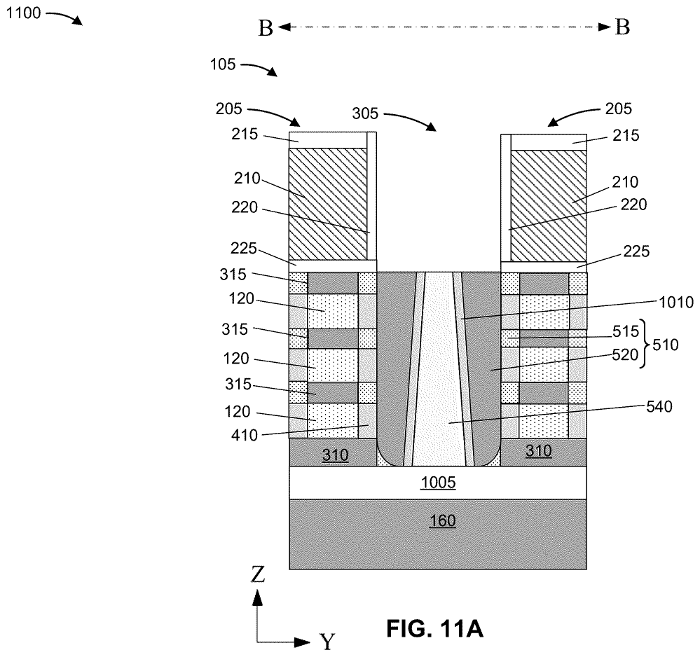

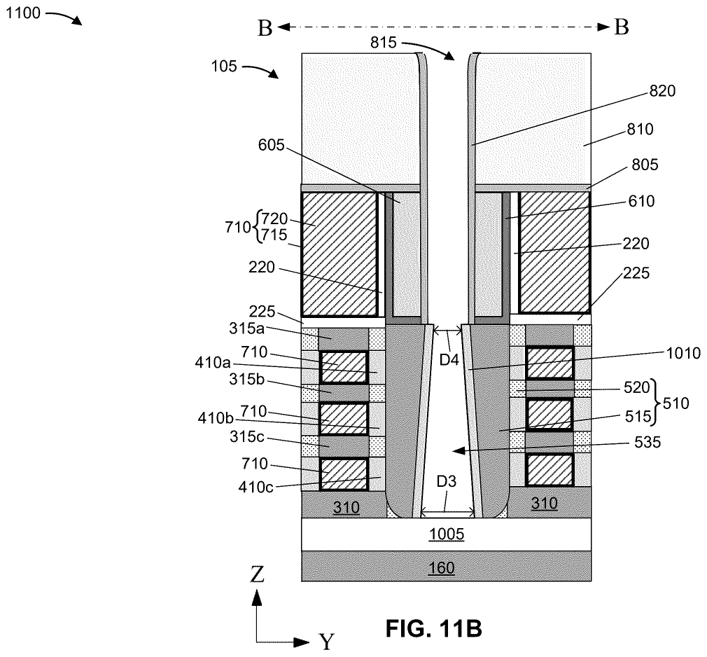

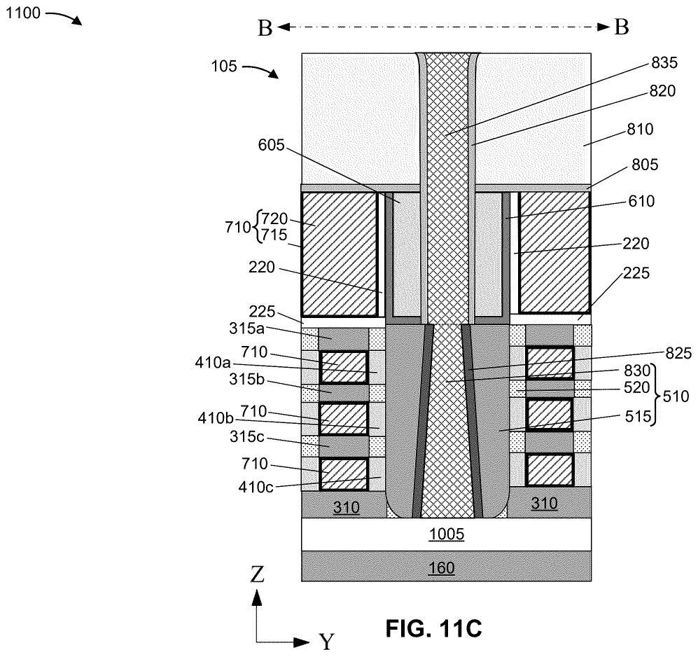

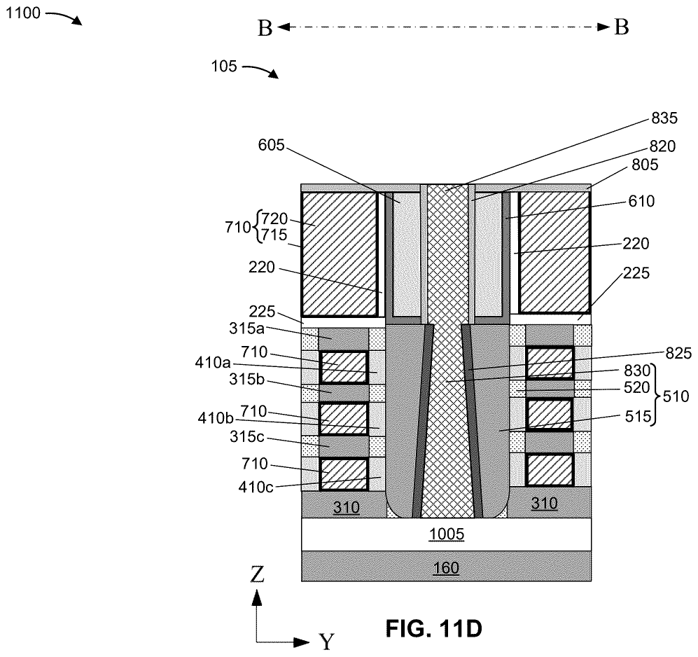

FIGS. 11A-11D are diagrams of an example implementation 1100 of forming the semiconductor device 105 described herein. The example implementation 1100 is similar to the example implementation 1000 described in connection with FIGS. 10A-10F. However, in the example implementation 1100, the bottom isolation layer 1005 may extend under the mesa regions 310. In some implementations, the bottom isolation layer 1005 is formed above the semiconductor substrate 110 prior to formation of the layer stack 115.

Additionally and/or alternatively, and as shown in FIG. 11B, the cavity 535 (e.g., the hollow core) of the source/drain region 510 may have a different cross-sectional profile than the cross-sectional profile illustrated in FIG. 10A in the example implementation 1000. In particular, the cavity 535 (e.g., the hollow core) of the source/drain region 510 may have a tapered cross-sectional profile in which a bottom width (e.g., in the y-direction) of the cavity 535 (indicated in FIG. 11B as a dimension D3) is greater than a top width (e.g., in the y-direction) of the cavity 535 (indicated in FIG. 11B as a dimension D4). The width of the cavity 535 may non-uniform from the top of the cavity 535 to the bottom of the cavity 535.

As further shown in FIGS. 11C and 11D, the metal core 830 of the source/drain region 510 may have a tapered cross-sectional profile in which a bottom width (e.g., in the y-direction) of the metal core 830 (dimension D3) is greater than a top width (e.g., in the y-direction) of the metal core 830 (dimension D4). The width of the metal core 830 may non-uniform from the top of the source/drain region 510 to the bottom of the source/drain region 510 in that the metal core 830 may conform to the profile of the cavity 535.

As indicated above, FIGS. 11A-11D are provided as an example. Other examples may differ from what is described with regard to FIGS. 11A-11D.

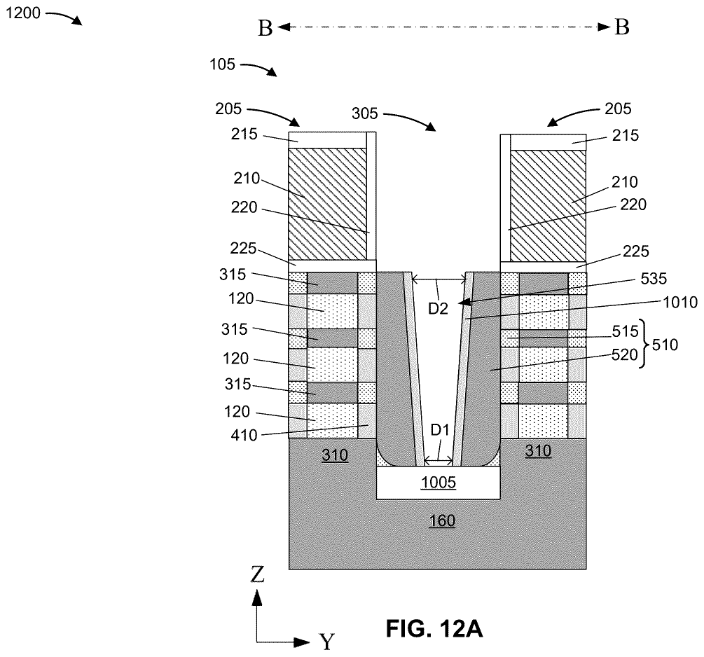

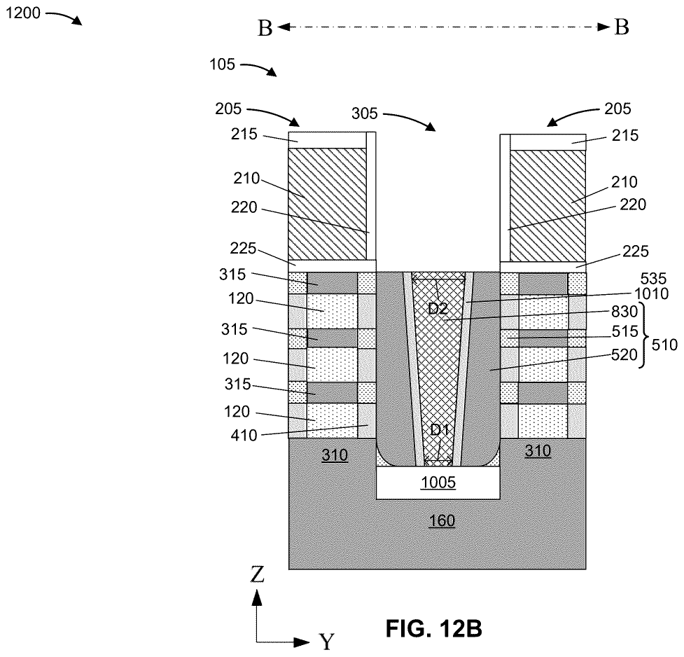

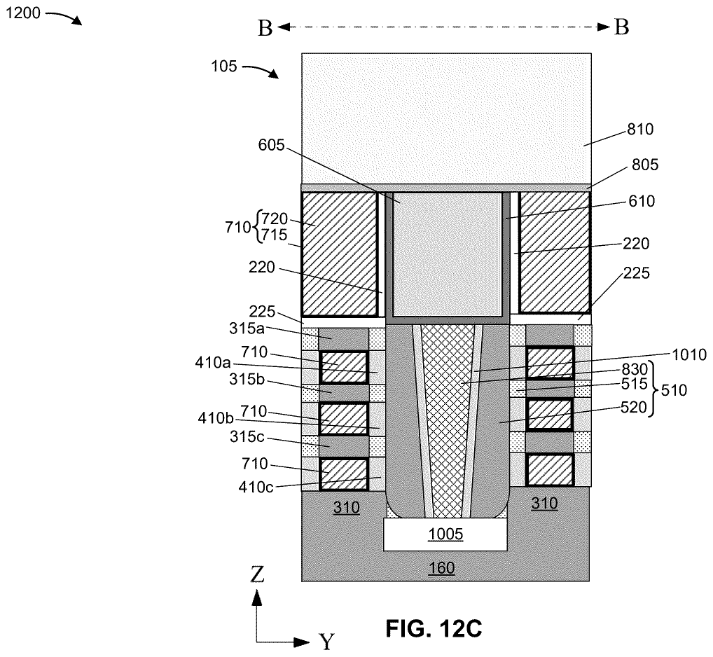

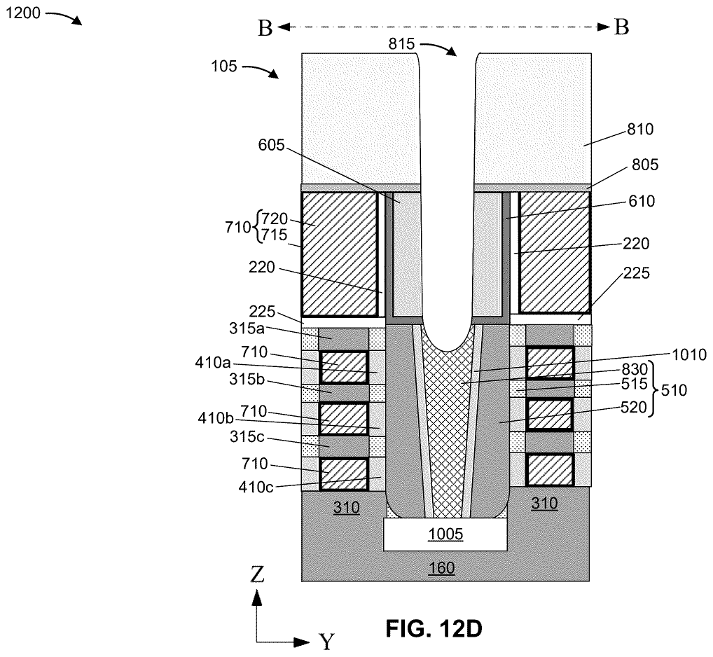

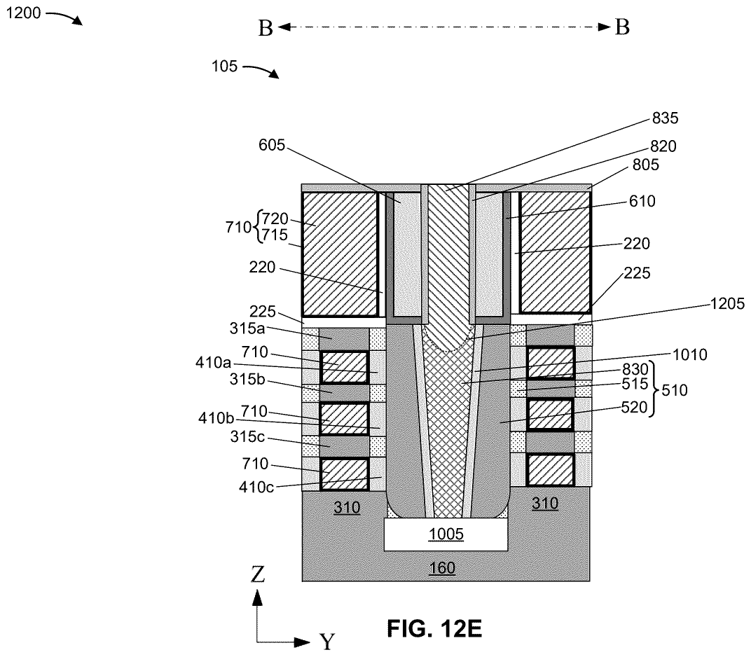

FIGS. 12A-12E are diagrams of an example implementation 1200 of forming the semiconductor device 105 described herein. The example implementation 1200 is similar to the example implementation 1000 described in connection with FIGS. 10A-10F in that the cavity 535 (e.g., the hollow core) extends vertically fully through the source/drain region 510 in the example implementation 1200. Moreover, the metal core 830 is formed in the cavity 535 such that the metal core 830 extends vertically fully through the source/drain region 510 in the example implementation 1200.

However, the example implementation 1200 differs from the example implementation 1000 described in connection with FIGS. 10A-10F in that the metal core 830 is formed in the cavity 535 through the source/drain recess 305 prior to formation of the dielectric layer 605 and prior to the replacement gate process illustrated in FIGS. 7A and 7B, whereas the metal core 830 is formed in the cavity 535 through the contact recess 815 after formation of the dielectric layer 605 and after the replacement gate process illustrated in FIGS. 7A and 7B.

In the example implementation 1200, the sacrificial plug 540 is omitted, and the metal core 830 is formed in the cavity 535 and covered by the dielectric layer 605 (as shown in FIGS. 12B and 12C). The metal core 830 may have a tapered cross-sectional profile where the bottom width of the metal core 830 (dimension D1 in FIG. 12B) is less than the top width of the metal core 830 (dimension D2 in FIG. 12B). However, other cross-sectional profiles for the metal core 830 are within the scope of the present disclosure.

As shown in FIG. 12D, the contact recess 815 is formed after the replacement gate process illustrated in FIGS. 7A and 7B, and the top of the metal core 830 is revealed through the contact recess 815. In some implementations, the contact recess 815 is formed such that the bottom of the contact recess 815 is recessed within the metal core 830.

As, shown in FIG. 12E, the sidewall liners 820 and the source/drain contact 835 are formed in the contact recess 815 such that the contact recess 815 lands on the top of the metal core 830. In some implementations, the metal core 830 and the source/drain contact 835 are formed of the same electrically conductive material. In some implementations, the metal core 830 and the source/drain contact 835 are formed of different electrically conductive materials. For example, the metal core 830 may be formed of a high melting point material such as ruthenium (Ru), and the source/drain contact 835 may be formed of a relatively lower melting point material such as cobalt (Co). However, other combinations of materials for the metal core 830 and the source/drain contact 835 are within the scope of the present disclosure.

As indicated above, the contact recess 815 may be formed such that the bottom of the contact recess 815 is recessed within the metal core 830. Thus, the bottom of the source/drain contact 835 may be recessed below the top surface of the metal core 830. Accordingly, an interface 1205 between the metal core 830 and the source/drain contact 835 may have a curved or arc-shaped cross-sectional profile where the curve or arc faces downward in the semiconductor device 105. However, other cross-sectional profiles for the interface 1205 between the metal core 830 and the source/drain contact 835 are within the scope of the present disclosure.

In the example implementation 1200 illustrated in FIGS. 12A-12E, the metal core 830 is illustrated as being formed on the capping layer 1010 of the source/drain region 510 and the metal silicide layer 825 is omitted. However, in other implementations, the capping layer 1010 may be omitted, and the metal silicide layer 825 may be formed on the second epitaxial layer 520 in the source/drain recess 305. In these implementations, the metal core 830 may be formed on the metal silicide layer 825 in the source/drain recess 305.

As indicated above, FIGS. 12A-12E are provided as an example. Other examples may differ from what is described with regard to FIGS. 12A-12E.

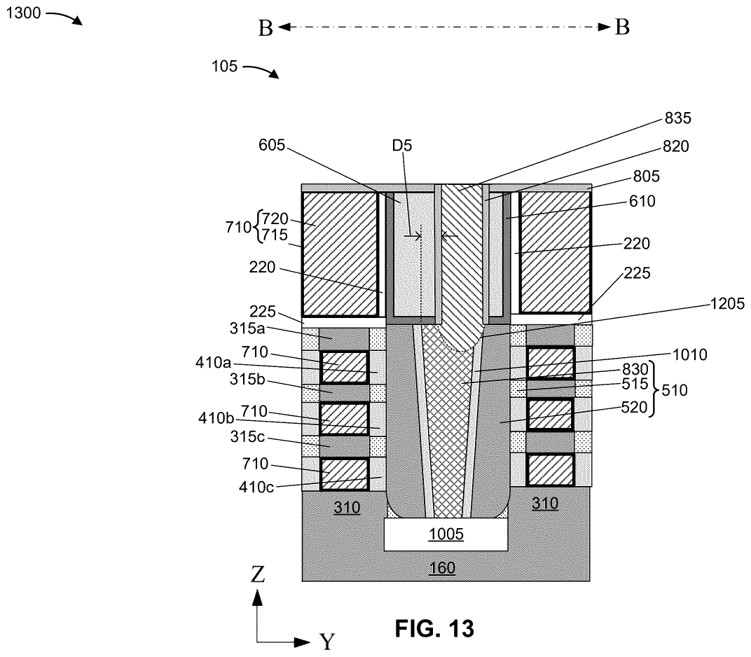

FIG. 13 is a diagram of an example implementation 1300 of the semiconductor device 105 described herein. As shown in FIG. 13, the example implementation 1300 of the semiconductor device 105 is similar to the example implementations illustrated in FIGS. 1-12E in that a source/drain region 510 of a nanostructure transistor of the semiconductor device 105 has a metal core 830 that is electrically coupled to a source/drain contact 835. However, in the example implementation 1300, the metal core 830 of the source/drain region 510 and the source/drain contact 835 are partially laterally offset by a distance (indicated in FIG. 13 as a dimension D5). The partial lateral offset between the metal core 830 of the source/drain region 510 and the source/drain contact 835 may result from an overlay shift during formation of the contact recess 815. The partial lateral offset may result in a portion of the bottom surface of the source/drain contact 835 being in contact with the capping layer 1010 and/or with the second epitaxial layer 520. Additionally and/or alternatively, the partial lateral offset may result in a portion of the top surface of the metal core 830 being in contact with the sidewall liners 820 and/or with the dielectric layer 605.

As indicated above, FIG. 13 is provided as an example. Other examples may differ from what is described with regard to FIG. 13.

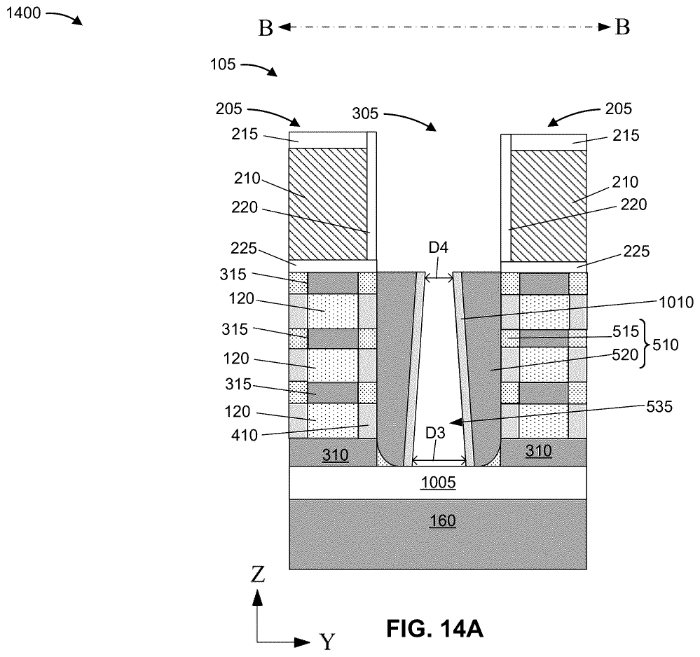

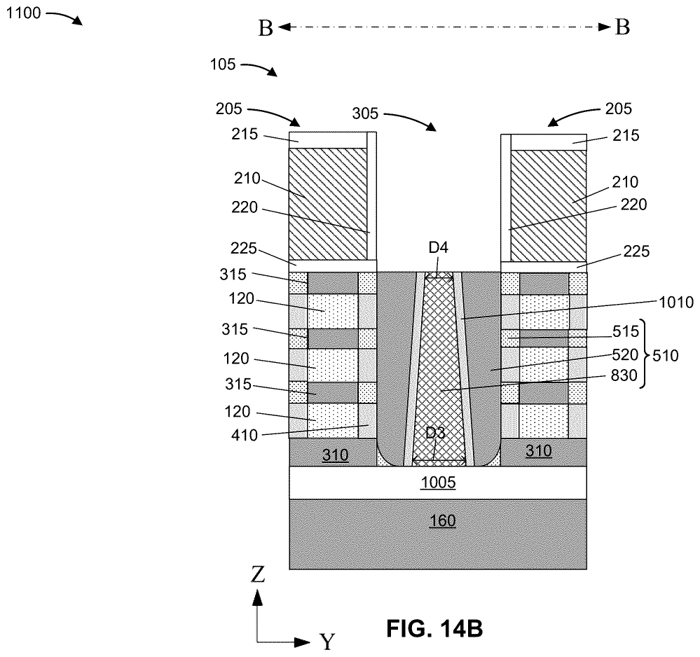

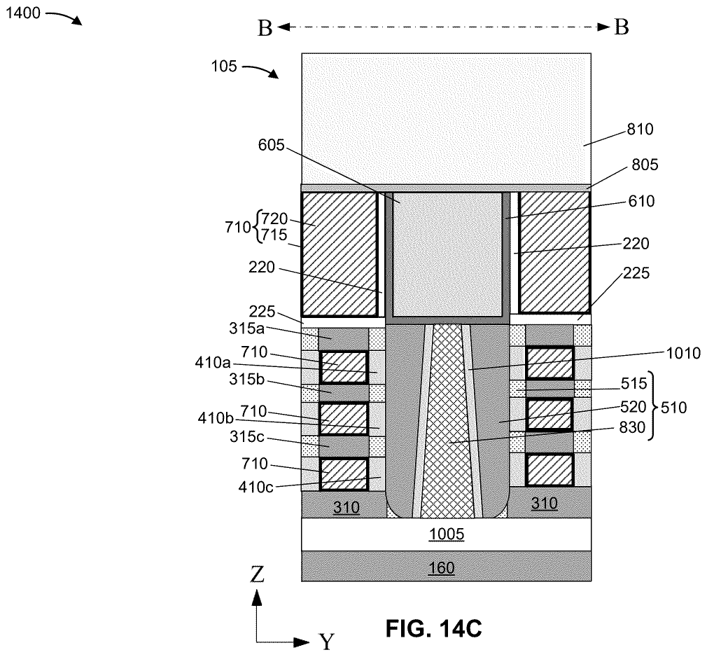

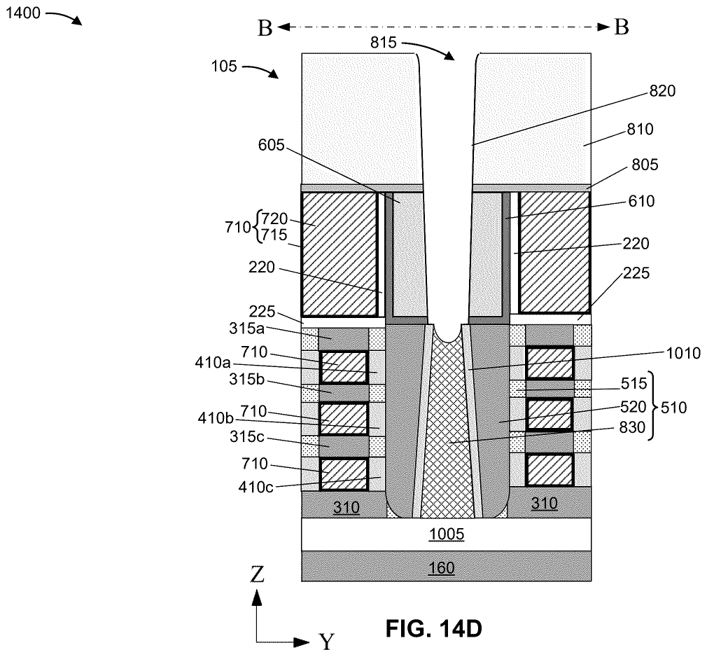

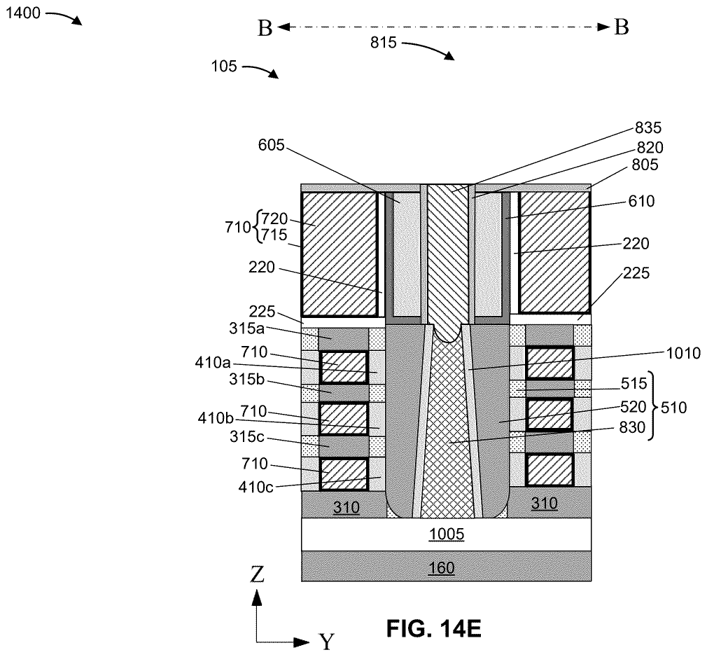

FIGS. 14A-14E are diagrams of an example implementation 1400 of forming the semiconductor device 105 described herein. The example implementation 1400 is similar to the example implementation 1100 described in connection with FIGS. 11A-11D in that the cavity 535 (e.g., the hollow core) extends vertically fully through the source/drain region 510 in the example implementation 1400. Moreover, the metal core 830 is formed in the cavity 535 such that the metal core 830 extends vertically fully through the source/drain region 510 in the example implementation 1400.

However, the example implementation 1400 differs from the example implementation 1100 described in connection with FIGS. 11A-11D in that the metal core 830 is formed in the cavity 535 through the source/drain recess 305 prior to formation of the dielectric layer 605 and prior to the replacement gate process illustrated in FIGS. 7A and 7B, whereas the metal core 830 is formed in the cavity 535 through the contact recess 815 after formation of the dielectric layer 605 and after the replacement gate process illustrated in FIGS. 7A and 7B.

In the example implementation 1400, the sacrificial plug 540 is omitted, and the metal core 830 is formed in the cavity 535 and covered by the dielectric layer 605 (as shown in FIGS. 14B and 14C). The metal core 830 may have a tapered cross-sectional profile where the bottom width of the metal core 830 (dimension D3 in FIG. 14B) is greater than the top width of the metal core 830 (dimension D4 in FIG. 14B). However, other cross-sectional profiles for the metal core 830 are within the scope of the present disclosure.

As shown in FIG. 14D, the contact recess 815 is formed after the replacement gate process illustrated in FIGS. 7A and 7B, and the top of the metal core 830 is revealed through the contact recess 815. In some implementations, the contact recess 815 is formed such that the bottom of the contact recess 815 is recessed within the metal core 830.

As, shown in FIG. 14E, the sidewall liners 820 and the source/drain contact 835 are formed in the contact recess 815 such that the contact recess 815 lands on the top of the metal core 830. In some implementations, the metal core 830 and the source/drain contact 835 are formed of the same electrically conductive material. In some implementations, the metal core 830 and the source/drain contact 835 are formed of different electrically conductive materials. For example, the metal core 830 may be formed of a high melting point material such as ruthenium (Ru), and the source/drain contact 835 may be formed of a relatively lower melting point material such as cobalt (Co). However, other combinations of materials for the metal core 830 and the source/drain contact 835 are within the scope of the present disclosure.

As indicated above, the contact recess 815 may be formed such that the bottom of the contact recess 815 is recessed within the metal core 830. Thus, the bottom of the source/drain contact 835 may be recessed below the top surface of the metal core 830. Accordingly, the interface between the metal core 830 and the source/drain contact 835 may have a curved or arc-shaped cross-sectional profile where the curve or arc faces downward in the semiconductor device 105. However, other cross-sectional profiles for the interface between the metal core 830 and the source/drain contact 835 are within the scope of the present disclosure.

In the example implementation 1400 illustrated in FIGS. 14A-14E, the metal core 830 is illustrated as being formed on the capping layer 1010 of the source/drain region 510 and the metal silicide layer 825 is omitted. However, in other implementations, the capping layer 1010 may be omitted, and the metal silicide layer 825 may be formed on the second epitaxial layer 520 in the source/drain recess 305. In these implementations, the metal core 830 may be formed on the metal silicide layer 825 in the source/drain recess 305.

As indicated above, FIGS. 14A-14E are provided as an example. Other examples may differ from what is described with regard to FIGS. 14A-14E.

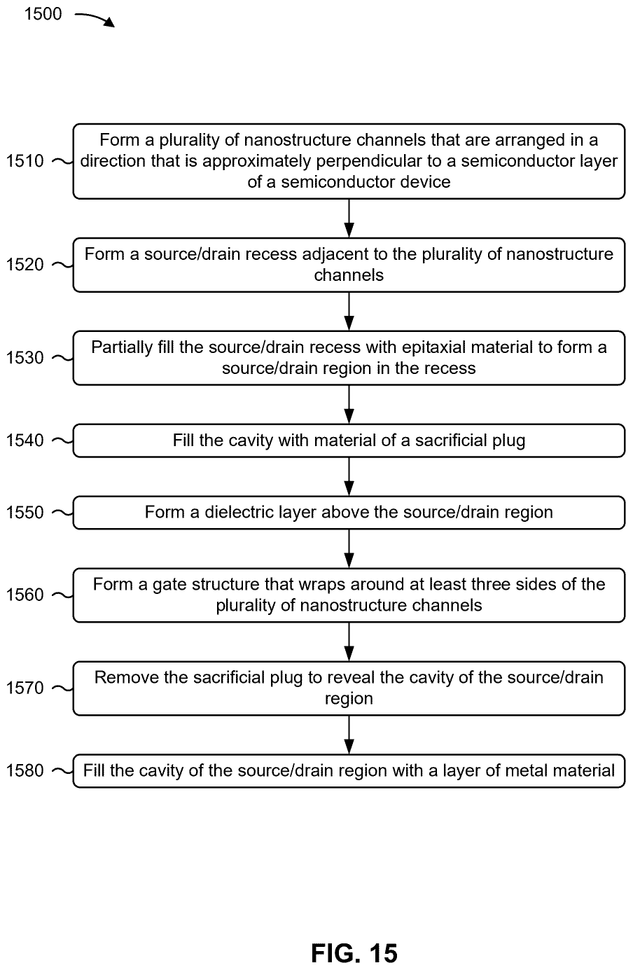

FIG. 15 is a flowchart of an example process 1500 associated with forming a semiconductor device described herein. In some implementations, one or more process blocks of FIG. 15 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 15, process 1500 may include forming a plurality of nanostructure channels that are arranged in a direction that is approximately perpendicular to a semiconductor layer of a semiconductor device (block 1510). For example, one or more semiconductor processing tools may be used to form a plurality of nanostructure channels (e.g., nanostructure channels 315, 315a-315c) that are arranged in a direction (e.g., a z-direction) that is approximately perpendicular to a semiconductor layer (e.g., a semiconductor substrate 110) of a semiconductor device (e.g., a semiconductor device 105), as described herein.

As further shown in FIG. 15, process 1500 may include forming a source/drain recess adjacent to the plurality of nanostructure channels (block 1520). For example, one or more semiconductor processing tools may be used to form a source/drain recess (e.g., a source/drain recess 305) adjacent to the plurality of nanostructure channels, as described herein.

As further shown in FIG. 15, process 1500 may include partially filling the source/drain recess with epitaxial material to form a source/drain region in the recess (block 1530). For example, one or more semiconductor processing tools may be used to partially fill the source/drain recess with epitaxial material (e.g., a first epitaxial layer 515, a second epitaxial layer 520, a merged region 525, non-contiguous second epitaxial regions 530) to form a source/drain region (e.g., a source/drain region 510) in the recess, as described herein. In some implementations, the source/drain region has a cavity (e.g., a cavity 535 that extends into the source/drain region 510 from a top of the source/drain region 510).

As further shown in FIG. 15, process 1500 may include filling the cavity with material of a sacrificial plug (block 1540). For example, one or more semiconductor processing tools may be used to fill the cavity with material of a sacrificial plug (e.g., a sacrificial plug 540), as described herein.

As further shown in FIG. 15, process 1500 may include forming a dielectric layer above the source/drain region (block 1550). For example, one or more semiconductor processing tools may be used to form a dielectric layer (e.g., a dielectric layer 605) above the source/drain region, as described herein.

As further shown in FIG. 15, process 1500 may include forming a gate structure that wraps around at least three sides of the plurality of nanostructure channels (block 1560). For example, one or more semiconductor processing tools may be used to form a gate structure (e.g., a gate structure 710) that wraps around at least three sides of the plurality of nanostructure channels, as described herein.

As further shown in FIG. 15, process 1500 may include removing the sacrificial plug to reveal the cavity of the source/drain region (block 1570). For example, one or more semiconductor processing tools may be used to remove the sacrificial plug to reveal the cavity of the source/drain region, as described herein.

As further shown in FIG. 15, process 1500 may include filling the cavity of the source/drain region with a layer of metal material (block 1580). For example, one or more semiconductor processing tools may be used to fill the cavity of the source/drain region with a layer of metal material (e.g., a metal core 830), as described herein.

Process 1500 may include additional implementations, such as any single implementation or any combination of implementations described below and/or in connection with one or more other processes described elsewhere herein.

In a first implementation, filling the cavity of the source/drain region with the layer of metal material comprises forming, after removing the sacrificial plug, a source/drain contact (e.g., a source/drain contact 835) such that the source/drain contact extends into the cavity of the source/drain region.

In a second implementation, alone or in combination with the first implementation, process 1500 includes forming, after forming the gate structure, a recess (e.g., a contact recess 815) through the dielectric layer and to the source/drain region, where forming the source/drain contact includes depositing the layer of metal material of the source/drain contact in the cavity through the recess.

In a third implementation, alone or in combination with one or more of the first and second implementations, process 1500 includes removing, through the recess, the sacrificial plug from the cavity of the source/drain region.

In a fourth implementation, alone or in combination with one or more of the first through third implementations, the epitaxial material of the source/drain region includes a first semiconductor material, the sacrificial plug includes a second semiconductor material, and the first semiconductor material and the second semiconductor material are different semiconductor materials.

In a fifth implementation, alone or in combination with one or more of the first through fourth implementations, process 1500 includes forming a metal silicide layer (e.g., a metal silicide layer 825) on sidewalls of the cavity, where filling the cavity with the material of the layer of metal material includes depositing the layer of metal material on the metal silicide layer.

In a sixth implementation, alone or in combination with one or more of the first through fifth implementations, the cavity extends fully through the source/drain region from a top of the source/drain region to a bottom of the source/drain region, and the layer of metal material extends fully through the source/drain region from a top of the source/drain region to a bottom of the source/drain region.

In a seventh implementation, alone or in combination with one or more of the first through sixth implementations, process 1500 includes forming a silicon (Si) capping layer (e.g., a capping layer 1010) on sidewalls of the cavity, where filling the cavity with the material of the sacrificial plug includes depositing the sacrificial plug on the silicon capping layer.

In an eighth implementation, alone or in combination with one or more of the first through seventh implementations, process 1500 includes performing a salicidation process to form a metal silicide layer (e.g., a metal silicide layer 825) from the silicon capping layer from the sidewalls of the cavity after removing the sacrificial plug.

In a ninth implementation, alone or in combination with one or more of the first through eighth implementations, the cavity extends partially into the source/drain region, and the layer of metal material extends into and lands on a bottom portion of the source/drain region.

Although FIG. 15 shows example blocks of process 1500, in some implementations, process 1500 includes additional blocks, fewer blocks, different blocks, or differently arranged blocks than those depicted in FIG. 15. Additionally, or alternatively, two or more of the blocks of process 1500 may be performed in parallel.

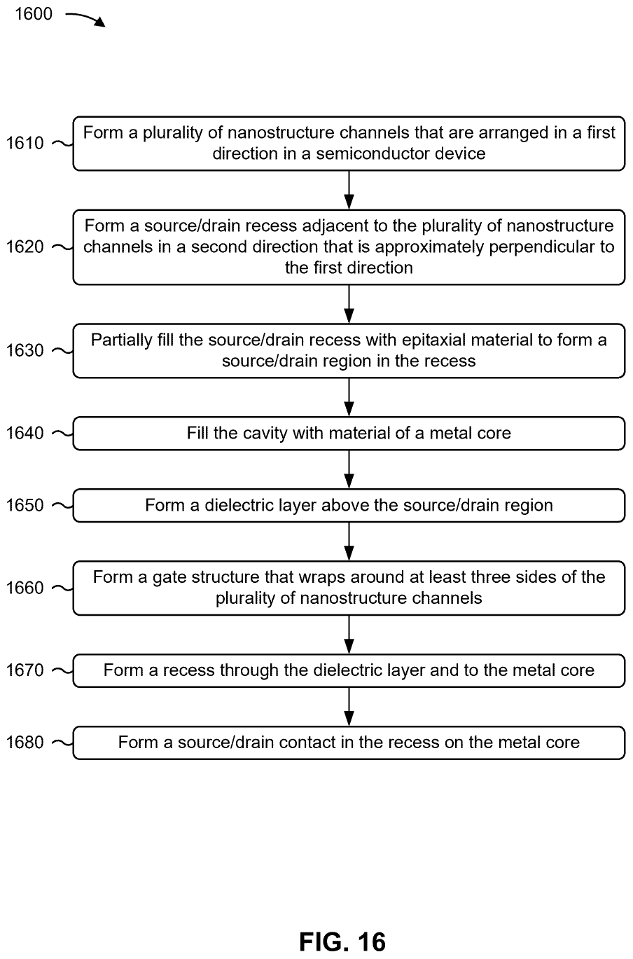

FIG. 16 is a flowchart of an example process 1600 associated with forming a semiconductor device described herein. In some implementations, one or more process blocks of FIG. 16 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 16, process 1600 may include forming a plurality of nanostructure channels that are arranged in a first direction in a semiconductor device (block 1610). For example, one or more semiconductor processing tools may be used to form a plurality of nanostructure channels (e.g., nanostructure channels 315, 315a-315c) that are arranged in a first direction (e.g., a z-direction) in a semiconductor device (e.g., a semiconductor device 105), as described herein.

As further shown in FIG. 16, process 1600 may include forming a source/drain recess adjacent to the plurality of nanostructure channels in a second direction that is approximately perpendicular to the first direction (block 1620). For example, one or more semiconductor processing tools may be used to form a source/drain recess (e.g., a source/drain recess 305) adjacent to the plurality of nanostructure channels in a second direction (e.g., a y-direction) that is approximately perpendicular to the first direction, as described herein.

As further shown in FIG. 16, process 1600 may include partially filling the source/drain recess with epitaxial material to form a source/drain region in the recess (block 1630). For example, one or more semiconductor processing tools may be used to partially fill the source/drain recess with epitaxial material (e.g., a first epitaxial layer 515, a second epitaxial layer 520, a merged region 525, non-contiguous second epitaxial regions 530) to form a source/drain region (e.g., a source/drain region 510) in the recess, as described herein. In some implementations, the source/drain region has a cavity (e.g., a cavity 535 that extends into the source/drain region 510 from a top of the source/drain region 510).

As further shown in FIG. 16, process 1600 may include filling the cavity with material of a metal core (block 1640). For example, one or more semiconductor processing tools may be used to fill the cavity with material of a metal core (e.g., a metal core 830), as described herein.

As further shown in FIG. 16, process 1600 may include forming a dielectric layer above the source/drain region (block 1650). For example, one or more semiconductor processing tools may be used to form a dielectric layer (e.g., a dielectric layer 605) above the source/drain region, as described herein.

As further shown in FIG. 16, process 1600 may include forming a gate structure that wraps around at least three sides of the plurality of nanostructure channels (block 1660). For example, one or more semiconductor processing tools may be used to form a gate structure (e.g., a gate structure 710) that wraps around at least three sides of the plurality of nanostructure channels, as described herein.

As further shown in FIG. 16, process 1600 may include forming a recess through the dielectric layer and to the metal core (block 1670). For example, one or more semiconductor processing tools may be used to form a recess (e.g., a contact recess 815) through the dielectric layer and to the metal core, as described herein.

As further shown in FIG. 16, process 1600 may include forming a source/drain contact in the recess on the metal core (block 1680). For example, one or more semiconductor processing tools may be used to form a source/drain contact (e.g., a source/drain contact 835) in the recess on the metal core, as described herein.

Process 1600 may include additional implementations, such as any single implementation or any combination of implementations described below and/or in connection with one or more other processes described elsewhere herein.

In a first implementation, forming the recess includes forming the recess such that the recess extends into a portion of the metal core.

In a second implementation, alone or in combination with the first implementation, forming the source/drain contact includes forming the source/drain contact such that a bottom of the source/drain contact extends into the portion of the metal core.

In a third implementation, alone or in combination with one or more of the first and second implementations, process 1600 includes forming a silicon (Si) capping layer (e.g., a capping layer 1010) on sidewalls of the cavity, where filling the cavity with the material of the metal core includes forming the material of metal core on the silicon capping layer.

In a fourth implementation, alone or in combination with one or more of the first through third implementations, a top width of the cavity (e.g., a dimension D2) at a top of the cavity is greater than a bottom width (e.g., a dimension D1) of the cavity at a bottom of the cavity.

In a fifth implementation, alone or in combination with one or more of the first through fourth implementations, the metal core includes a first metal, the source/drain contact includes a second metal, and the first metal and the second metal are different metals.

Although FIG. 16 shows example blocks of process 1600, in some implementations, process 1600 includes additional blocks, fewer blocks, different blocks, or differently arranged blocks than those depicted in FIG. 16. Additionally, or alternatively, two or more of the blocks of process 1600 may be performed in parallel.

In this way, a source/drain region is formed for a nanostructure transistor of a semiconductor device such that a hollow cavity extends into the source/drain region from a top of the source/drain region into the source/drain region. In some implementations, the cavity extends fully through the depth of the source/drain region. The cavity results from partial epitaxial growth of one or more epitaxial layers of the source/drain region. A metal core of the source/drain region is formed in the cavity and electrically coupled to a source/drain contact of a nanostructure transistor such that electrically conductive material is recessed within the source/drain region. This provides a greater amount of surface area for the source/drain contact to contact the source/drain region than if the source/drain region were fully filled in with epitaxially-grown semiconductor material. The increased contact surface area provides for reduced contact resistance between the source/drain region and the source/drain contact, because of the less-restricted current flow path between the source/drain region and the source/drain contact. In this way, the reduced contact resistance between the source/drain region and the source/drain contact enables a greater power efficiency to be achieved for the nanostructure transistor and/or enables increased switching speeds to be achieved for the nanostructure transistor, among other examples.

As described in greater detail above, some implementations described herein provide a method. The method includes forming a plurality of nanostructure channels that are arranged in a direction that is approximately perpendicular to a semiconductor layer of a semiconductor device. The method includes forming a source/drain recess adjacent to the plurality of nanostructure channels. The method includes partially filling the source/drain recess with epitaxial material to form a source/drain region in the recess, where the source/drain region has a cavity. The method includes filling the cavity with material of a sacrificial plug. The method includes forming a dielectric layer above the source/drain region. The method includes forming a gate structure that wraps around at least three sides of the plurality of nanostructure channels. The method includes removing the sacrificial plug to reveal the cavity of the source/drain region. The method includes filling the cavity of the source/drain region with a layer of metal material.

As described in greater detail above, some implementations described herein provide a method. The method includes forming a plurality of nanostructure channels that are arranged in a first direction in a semiconductor device. The method includes forming a source/drain recess adjacent to the plurality of nanostructure channels in a second direction that is approximately perpendicular to the first direction. The method includes partially filling the source/drain recess with epitaxial material to form a source/drain region in the recess, where the source/drain region has a cavity. The method includes filling the cavity with material of a metal core. The method includes forming a dielectric layer above the source/drain region. The method includes forming a gate structure that wraps around at least three sides of the plurality of nanostructure channels. The method includes forming a recess through the dielectric layer and to the metal core. The method includes forming a source/drain contact in the recess on the metal core.

As described in greater detail above, some implementations described herein provide a semiconductor device. The semiconductor device includes a plurality of nanostructure channels arranged in a first direction and that extend in a second direction that is approximately perpendicular to the first direction. The semiconductor device includes a gate structure wrapped around the plurality of nanostructure channels. The semiconductor device includes a source/drain region, adjacent to a side of the gate structure and adjacent to ends of the plurality of nanostructure channels in the second direction. The source/drain region includes a metal core and one or more epitaxial layers laterally surrounding the metal core. The semiconductor device includes a source/drain contact on and in contact with the metal core.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a plurality of nanostructure channels that are arranged in a direction that is approximately perpendicular to a semiconductor layer of a semiconductor device;
forming a source/drain recess adjacent to the plurality of nanostructure channels;
partially filling the source/drain recess with epitaxial material to form a source/drain region in the recess,
wherein the source/drain region has a cavity;
filling the cavity with material of a sacrificial plug;
forming a dielectric layer above the source/drain region;
forming a gate structure that wraps around at least three sides of the plurality of nanostructure channels;
removing the sacrificial plug to reveal the cavity of the source/drain region; and
filling the cavity of the source/drain region with a layer of metal material.

2. The method of claim 1, wherein filling the cavity of the source/drain region with the layer of metal material comprises:
forming, after removing the sacrificial plug, a source/drain contact such that the source/drain contact extends into the cavity of the source/drain region.

3. The method of claim 2, further comprising:
forming, after forming the gate structure, a recess through the dielectric layer and to the source/drain region,
wherein forming the source/drain contact comprises:
depositing the layer of metal material of the source/drain contact in the cavity through the recess.

4. The method of claim 3, further comprising:
removing, through the recess, the sacrificial plug from the cavity of the source/drain region.

5. The method of claim 4, wherein the epitaxial material of the source/drain region comprises a first semiconductor material;
wherein the sacrificial plug comprises a second semiconductor material; and
wherein the first semiconductor material and the second semiconductor material are different semiconductor materials.

6. The method of claim 1, further comprising:
forming a metal silicide layer on sidewalls of the cavity,
wherein filling the cavity with the layer of metal material comprises:
depositing the layer of metal material on the metal silicide layer.

7. The method of claim 1, wherein the cavity extends fully through the source/drain region from a top of the source/drain region to a bottom of the source/drain region; and
wherein the layer of metal material extends fully through the source/drain region from a top of the source/drain region to a bottom of the source/drain region.

8. The method of claim 1, further comprising:
forming a silicon (Si) capping layer on sidewalls of the cavity,
wherein filling the cavity with the material of the sacrificial plug comprises:
depositing the sacrificial plug on the silicon capping layer.

9. The method of claim 8, further comprising:
performing a salicidation process to form a metal silicide layer from the silicon capping layer from the sidewalls of the cavity after removing the sacrificial plug.

10. The method of claim 1, wherein the cavity extends partially into the source/drain region; and
wherein the layer of metal material extends into and lands on a bottom portion of the source/drain region.

11. A method, comprising:
forming a plurality of nanostructure channels that are arranged in a first direction in a semiconductor device;
forming a source/drain recess adjacent to the plurality of nanostructure channels in a second direction that is approximately perpendicular to the first direction;
partially filling the source/drain recess with epitaxial material to form a source/drain region in the recess,
wherein the source/drain region has a cavity;
filling the cavity with material of a metal core;
forming a dielectric layer above the source/drain region;
forming a gate structure that wraps around at least three sides of the plurality of nanostructure channels;
forming a recess through the dielectric layer and to the metal core; and
forming a source/drain contact in the recess on the metal core.

12. The method of claim 11, wherein forming the recess comprises:
forming the recess such that the recess extends into a portion of the metal core.

13. The method of claim 12, wherein forming the source/drain contact comprises:
forming the source/drain contact such that a bottom of the source/drain contact extends into the portion of the metal core.

14. The method of claim 11, further comprising:
forming a silicon (Si) capping layer on sidewalls of the cavity,
wherein filling the cavity with the material of the metal core comprises:
depositing the metal core on the silicon capping layer.

15. The method of claim 11, wherein a top width of the cavity at a top of the cavity is greater than a bottom width of the cavity at a bottom of the cavity.

16. The method of claim 11, wherein the metal core comprises a first metal;
wherein the source/drain contact comprises a second metal; and
wherein the first metal and the second metal are different metals.

17. A semiconductor device, comprising:
a plurality of nanostructure channels arranged in a first direction and that extend in a second direction that is approximately perpendicular to the first direction;
a gate structure wrapped around the plurality of nanostructure channels;
a source/drain region, adjacent to a side of the gate structure and adjacent to ends of the plurality of nanostructure channels in the second direction, comprising:
a metal core; and
one or more epitaxial layers laterally surrounding the metal core; and
a source/drain contact on and in contact with the metal core.

18. The semiconductor device of claim 17, further comprising:
a metal silicide layer between the metal core and the one or more epitaxial layers.

19. The semiconductor device of claim 18, wherein the metal core vertically extends between a top-most nanostructure channel of the plurality of nanostructure channels and a bottom-most nanostructure channel of the plurality of nanostructure channels.

20. The semiconductor device of claim 19, wherein a portion of the one or more epitaxial layers is below a bottom of the metal core.
